(19) United States
(12) Patent Application Publication
(10) Pub. No.: US 2011/0177342 A1
(43) Pub. Date: Jul. 21, 2011

(54) Cured Organopolysiloxane Resin Film Having Gas Barrier Properties and Method Of Producing The Same

(76) Inventors: Maki Itoh, Tokyo (JP); Michitaka Suto, Kanagawa (JP); Nobuo Kushibiki, Kanagawa (JP); Hidekatsu Hatanaka, Chiba (JP); Katsuya Eguchi, Kanagawa (JP); Dimitris Elias Katsoulis, Midland, MI (US)

(21) Appl. No.: 13/003,316

(22) PCT Filed: Jun. 26, 2009
(86) PCT No.: PCT/JP2009/062174

§ 371 Date: Apr. 8, 2011

(30) Foreign Application Priority Data
Jul. 10, 2008 (JP) JP2008-180782

(51) Int. Cl. B32B 27/08; B32B 27/38; B32B 9/00; C23C 16/34; C23C 16/40; C23C 14/06; C23C 14/22; B05D 5/00; B05D 3/00

(52) U.S. Cl. 428/414; 428/447; 427/248.1; 427/527

(57) ABSTRACT

A cured organopolysiloxane resin film having gas barrier properties in which a layer of cured organopolysiloxane that contains an organic functional group, an organic group produced by the polymerization of polymerizable organic functional groups, or the hydrosilyl group or silanol group, is formed on a visible region-transparent film comprising cured organopolysiloxane resin yielded by hydrosilylation reaction-mediated crosslinking, and in which a silicon oxynitride layer, silicon nitride layer, or silicon oxide layer is formed on the aforementioned layer of cured organopolysiloxane. Also, a method of producing this cured organopolysiloxane resin film having gas barrier properties.

### TECHNICAL FIELD

The present invention relates to a cured organopolysiloxane resin film that exhibits, inter alia, excellent gas barrier properties, in which a transparent inorganic layer selected from the group consisting of a silicon oxynitride layer, silicon nitride layer, and silicon oxide layer is formed on a cured organopolysiloxane resin film that is transparent in the visible region. The present invention additionally relates to a method of producing this cured organopolysiloxane resin film.

### BACKGROUND ART

Film-type optical elements having various polymeric films as the substrate therein are beginning to be used in, for example, organic EL displays and liquid crystal displays. Moreover, the importance of film-type optical elements is increasing as these displays become thinner and lighter. Paper-type displays have recently become a topic, but this is a technology that will not be accomplished without polymer films.

Polymer films are one of the most successful technologies in the field of polymer materials; the most prominent polymer films are films made transparent by the biaxial stretching of a crystalline polymer film, such as polyethylene, polypropylene, and polyethylene terephthalate, and films of noncrystalline polymers such as polycarbonate and polymethyl methacrylate. All of these polymers are thermoplastic polymers, and free-standing films can be easily produced by adjusting the molecular weight and molecular weight distribution.

However, within the realm of crosslinked polymer films, it is difficult to commercially acquire a free-standing film other than polyimide films, and in practice crosslinked polymer films are often made available formed on an appropriate substrate. Because crosslinked polymers are formed by the crosslinking of a low molecular weight compound or low molecular weight oligomer, the formation of a film is frequently problematic due to the shrinkage produced during crosslinking and the internal stress generated by crosslinking. However, the melt flow seen at high temperatures with thermoplastic resins does not occur as a consequence of the crosslinked structure, thus offering the advantage that substantial deformation does not occur even at or above the glass-transition temperature.

Crosslinking reaction-cured organopolysiloxane resins are well known to exhibit an excellent heat resistance and an excellent optical transparency, and, among their optical properties, a characteristic feature of the cured organopolysiloxane resins is a low birefringence. Low birefringence is an important property for optical materials involved with imaging and is also an important property with regard to lowering the read error in optical recording. An excellent planarity is another characteristic feature of cured organopolysiloxane resin films.

Film-type optical elements have recently been receiving attention for application in particular to organic EL displays and liquid-crystal displays; however, strong gas barrier properties are required of the film substrate for film-type optical elements for organic EL displays and liquid-crystal displays in order to avoid performance degradation due to contact with, inter alia, water vapor or oxygen.

For example, Japanese Unexamined Application Publication No. [hereinafter referred to as “JP Kokai”] H8-224825 and US 2003/0228475 A1 disclose a gas barrier film comprising a thin film formed on a plastic film wherein the main component of this thin film is silicon oxide. A transparent, water vapor-barrier film comprising two types of silicon oxynitride layers formed on a resin substrate is disclosed in Japanese Patent No. 3859518 and JP Kokai 2003-206361. A gas barrier laminate comprising a silicon oxynitride layer formed on a resin substrate, e.g., a plastic film, is disclosed in JP Kokai 2004-276564 and US 2003/0228475 A1. JP Kokai 2006-123306 discloses a gas barrier laminate comprising a resin layer of which main component is a polyorganosilsesquioxane laminated on the surface of a plastic film and an inorganic compound layer of silicon oxide, silicon oxynitride, silicon oxycarbide, silicon carbide, silicon nitride, or silicon dioxide formed by a vacuum film formation procedure on the resin layer.

However, each of the substrates is a thermoplastic resin film, and as a consequence problems arise such as a poor heat resistance and a large birefringence. The present inventors therefore attempted to form a silicon oxynitride layer, that is, silicon oxynitride film on a hydrosilylation reaction-cured organopolysiloxane resin film as disclosed in WO 2005/111149 A1; however, it was discovered that the silicon oxynitride layer, that is, silicon oxynitride film did not adhere uniformly and that the gas barrier properties, such as the water vapor barrier performance, were inferior.

### PATENT REFERENCES

[Patent Reference 1] JP Kokai H8-224825 (JP 8-224825 A)
[Patent Reference 2] US 2003/0228475 A1
[Patent Reference 3] Japanese Patent No. 3859518 (JP 3859518 B)
[Patent Reference 4] JP Kokai 2004-276564 (JP 2004-276564 A)
[Patent Reference 5] JP Kokai 2006-123306 (JP 2006-123306 A)
[Patent Reference 6] WO 2005/111149 A1

The present inventors therefore carried out intensive investigations in order to develop a highly transparent, highly heat-resistant cured organopolysiloxane resin film, particularly free-standing film having high gas barrier properties, comprising a transparent inorganic layer, that is, transparent inorganic film selected from the group consisting of a silicon oxynitride layer, that is, silicon oxynitride film, silicon nitride layer, that is, silicon nitride film, and silicon oxide layer, that is, silicon oxide film, uniformly formed on a highly heat-resistant, visible region-transparent cured organopolysiloxane resin film, particularly free-standing film, wherein this transparent inorganic layer (transparent inorganic film) is strongly adhered to the aforementioned film. As a result of these investigations, the present inventors invented such a cured organopolysiloxane resin film, particularly free-standing cured organopolysiloxane resin film having high gas barrier properties and a method of producing such a cured organopolysiloxane resin film, particularly free-standing cured organopolysiloxane resin film having high gas barrier properties.

### SUMMARY OF THE INVENTION

### Problems to be Solved by the Invention

An object of the present invention is to provide a cured organopolysiloxane resin film, particularly free-standing film that is transparent in the visible region and exhibits an excellent heat resistance and that exhibits a high gas barrier performance due to an excellent adherence by a transparent inorganic layer, that is, transparent inorganic film selected from the group consisting of a silicon oxynitride layer, that is, silicon oxynitride film, silicon nitride layer, that is, silicon nitride film, and silicon oxide layer, that is, silicon oxide film, to the cured organopolysiloxane resin film, particularly free-standing film, and to provide a method of producing said cured organopolysiloxane resin film, particularly free-standing film having high gas barrier properties.

### Means Solving the Problems

This object is achieved by

“[1] A cured organopolysiloxane resin film having gas barrier properties characterized in that an organic functional group-containing cured organopolysiloxane layer is formed on a film which is transparent in the visible region and comprises a cured organopolysiloxane resin obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst,
   and a transparent inorganic layer selected from the group consisting of a silicon oxynitride layer, silicon nitride layer, and silicon oxide layer is formed on the cured organopolysiloxane layer.

[2] The cured organopolysiloxane resin film having gas barrier properties according to [1], characterized in that the organic functional group is an oxygen-containing organic functional group.

[3] The cured organopolysiloxane resin film having gas barrier properties according to [2], characterized in that the oxygen-containing organic functional group is an acrylic functional group, epoxy functional group, or oxetanyl functional group.

[3-1] The cured organopolysiloxane resin film having gas barrier properties according to [3], characterized in that the acrylic functional group is an acryloxy functional group.

[4] The cured organopolysiloxane resin film having gas barrier properties according to [3], characterized in that the acryloxy functional group is an acryloxyalkyl group or methacryloxyalkyl group and the epoxy functional group is a glycidoxyalkyl group or epoxycyclohexylalkyl group.

[5] The cured organopolysiloxane resin film having gas barrier properties according to [1], characterized in that the organopolysiloxane resin represented by the average siloxane unit formula (1) is composed of at least one siloxane unit represented by formula [X_{(3-b)}R¹_{b}SiO_{1/2}] (in the formula, X is C_{2 to} C₁₀ monovalent unsaturated aliphatic hydrocarbyl, R¹ is C_{1 to} C₁₀ monovalent hydrocarbyl other than X, and b is 0, 1, or 2) and at least one siloxane unit represented by formula [R²SiO_{3/2}] (in the formula, R² is C₁ to C₁₀ monovalent hydrocarbyl other than X), or at least one siloxane unit represented by formula [X_{(3-b)}R¹_{b}SiO_{1/2}] (in the formula, X is C₂ to C₁₀ monovalent unsaturated aliphatic hydrocarbyl, R¹ is C_{1 to} C₁₀ monovalent hydrocarbyl other than X, and b is 0, 1, or 2), at least one siloxane unit represented by formula [R²SiO_{3/2}] (in the formula, R² is C_{1 to} C₁₀ monovalent hydrocarbyl other than X), and at least one siloxane unit represented by formula [SiO_{4/2}].

[6] The cured organopolysiloxane resin film having gas barrier properties according to [5], characterized in that the organopolysiloxane resin is represented by the average siloxane unit formula

[X_{(3-b)}R¹)_{b}SiO_{1/2}]ᵥ[R²SiO_{3/2}]_{w} (2)

(in the formula, X, R¹, R², and b are defined as in [5], 0.8≦w≦1.0, and v+w=1) or by the average siloxane unit formula

[X_{(3-b)}R¹_{b}SiO_{1/2}]ₓ[R²SiO_{3/2}]_{y}[SiO_{4/2}]_{z} (3)

(in the formula, X, R¹, R², and b are defined as in [5], 0<x<0.4, 0.5<y<1, 0<z<0.4, and x+y+z=1).”.

The aforementioned object is also achieved by

“[7] A method of producing the cured organopolysiloxane resin film having gas barrier properties according to [1], said method being characterized by

coating and curing an organic functional group-containing curable organosilane or composition thereof or an organic functional group-containing curable organopolysiloxane or composition thereof on a film which is transparent in the visible region and comprises a cured organopolysiloxane resin obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst,
   to form on said film an organic functional group-containing cured organopolysiloxane layer; and

then forming, by vapor deposition, a transparent inorganic layer selected from the group consisting of a silicon oxynitride layer, silicon nitride layer, and silicon oxide layer, on the cured organopolysiloxane layer.

[8] The method of producing a cured organopolysiloxane resin film having gas barrier properties according to [7], characterized in that the organic functional group-containing curable organosilane or composition thereof is condensation reaction-curable, the organic functional group-containing curable organopolysiloxane is condensation reaction-curable, and the organic functional group-containing curable organopolysiloxane composition is condensation reaction-curable or hydrosilylation reaction-curable.

[9] The method of producing the cured organopolysiloxane resin film having gas barrier properties according to [7] or [8], characterized in that the organic functional group is an oxygen-containing organic functional group.

[10] The method of producing the cured organopolysiloxane resin film having gas barrier properties according to [9], characterized in that the oxygen-containing organic functional group is an acrylic functional group, epoxy functional group, or oxetanyl functional group.

[10-1] The method of producing a cured organopolysiloxane resin film having gas barrier properties according to [10], characterized in that the acrylic functional group is an acryloxy functional group.

[11] The method of producing a cured organopolysiloxane resin film having gas barrier properties according to [10], characterized in that the acrylic functional group is an acryloxyalkyl group or methacryloxyalkyl group and the epoxy functional group is a glycidoxyalkyl group or epoxycyclohexylalkyl group.

[12] The method of producing a cured organopolysiloxane resin film having gas barrier properties according to [7], characterized in that the silicon oxynitride layer is formed by a reactive ion plating procedure.”.

The aforementioned object is also achieved by

“[13] A cured organopolysiloxane resin film having gas barrier properties characterized in that a layer of cured organopolysiloxane having an organic group produced by polymerization between polymerizable organic functional groups, is formed on a film which is transparent in the visible region and comprises a cured organopolysiloxane resin obtained by a crosslinking reaction between
(A) an organopolysiloxane resin that is represented by the average siloxane unit formula

RₐSiO_{(4-a)/2} (2)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst,
   and a transparent inorganic layer selected from the group consisting of a silicon oxynitride layer, silicon nitride layer, and silicon oxide layer is formed on the cured organopolysiloxane layer.

[14] The cured organopolysiloxane resin film having gas barrier properties according to [13], characterized in that the polymerizable organic functional group is an oxygen-containing polymerizable organic functional group, and the organic group is an oxygen-containing organic group.

[15] The cured organopolysiloxane resin film having gas barrier properties according to [14], characterized in that the oxygen-containing polymerizable organic functional group is an acrylic functional group, epoxy functional group, oxetanyl functional group, or alkenyl ether functional group; the oxygen-containing organic group has a carbonyl group or ether bond.

[15-1] The cured organopolysiloxane resin film having gas barrier properties according to [15], characterized in that the acrylic functional group is an acryloxy functional group or acrylamide functional group.

[16] The cured organopolysiloxane resin film having gas barrier properties according to [15], characterized in that the acrylic functional group is an acryloxyalkyl group, methacryloxyalkyl group, acrylamidealkyl group or methacrylamidealkyl group; the epoxy functional group is a glycidoxyalkyl group or epoxycyclohexylalkyl group; the alkenyl ether functional group is a vinyloxyalkyl group; and the oxygen-containing organic group has a carboxylic acid ester bond, carboxylic acid amide bond or ether bond.

[17] The cured organopolysiloxane resin film having gas barrier properties according to [13], characterized in that the organopolysiloxane resin represented by the average siloxane unit formula (1) is composed of at least one siloxane unit represented by formula [X_{(3-b)}R¹_{b}SiO_{1/2}] (in the formula, X is C₂ to C₁₀ monovalent unsaturated aliphatic hydrocarbyl, R¹ is C_{1 to} C₁₀ monovalent hydrocarbyl other than X, and b is 0, 1, or 2) and at least one siloxane unit represented by formula [R²SiO_{3/2}] (in the formula, R² is C_{1 to} C₁₀ monovalent hydrocarbyl other than X), or at least one siloxane unit represented by formula [X_{(3-b)}R¹_{b}SiO_{1/2}] (in the formula, X is C_{2 to} C₁₀ monovalent unsaturated aliphatic hydrocarbyl, R¹ is C_{1 to} C₁₀ monovalent hydrocarbyl other than X, and b is 0, 1, or 2), at least one siloxane unit represented by formula [R²SiO_{3/2}] (in the formula, R² is C_{1 to} C₁₀ monovalent hydrocarbyl other than X), and at least one siloxane unit represented by formula [SiO_{4/2}].

[18] The cured organopolysiloxane resin film having gas barrier properties according to [17], characterized in that the organopolysiloxane resin is represented by the average siloxane unit formula

[X_{(3-b)}R¹_{b}SiO_{1/2}]ᵥ[R²SiO_{3/2}]_{w} (2)

(in the formula, X, R¹, R², and b are defined as in [17], 0.8<w<1.0, and v+w=1) or by the average siloxane unit formula

[X_{(3-b)}R¹_{b}SiO_{1/2}]ₓ[R²SiO_{3/2}]_{y}[SiO_{4/2}]_{z} (3)

(in the formula, X, R¹, R², and b are defined as in [17], 0<x<0.4, 0.5<y<1, 0<z<0.4, and x+y+z=1).”.

The aforementioned object is also achieved by

“[19] A method of producing the cured organopolysiloxane resin film having gas barrier properties according to [13], said method being characterized by

coating an organopolysiloxane that has polymerizable organic functional groups on a film which is transparent in the visible region and comprises a cured organopolysiloxane resin obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst;

crosslinking said organopolysiloxane by polymerization of the polymerizable organic functional groups with each other to form a layer of cured organopolysiloxane having organic groups on said film; and

then forming, by vapor deposition, a transparent inorganic layer selected from the group consisting of a silicon oxynitride layer, silicon nitride layer, and silicon oxide layer, on the cured organopolysiloxane layer.

[20] A method of producing a cured organopolysiloxane resin film having gas barrier properties according to [13], said method being characterized by

coating a polymerizable organic functional group- and crosslinking group-containing curable organopolysiloxane or composition thereof on a film which is transparent in the visible region and comprises a cured organopolysiloxane resin obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C₂ to C₁₀ unsaturated aliphatic hydrocarbyl per molecule and
(B) an organosilicon compound having at least two silicon-bonded hydrogen atoms per molecule
   in the presence of
(C) a hydrosilylation reaction catalyst;

reacting the crosslinking groups with each other and polymerizing the polymerizable organic functional groups with each other to form a layer of cured organopolysiloxane having organic groups on said film; and

then forming, by vapor deposition, a transparent inorganic layer selected from the group consisting of a silicon oxynitride layer, silicon nitride layer, and silicon oxide layer, on the cured organopolysiloxane layer.

[21] The method of producing a cured organopolysiloxane resin film having gas barrier properties according to [19] or [20], characterized in that the polymerizable organic functional group is an oxygen-containing polymerizable organic functional group, and the organic group is an oxygen-containing organic group.

[22] The method of producing a cured organopolysiloxane resin film having gas barrier properties according to [21], characterized in that the oxygen-containing polymerizable organic functional group is an acrylic functional group, epoxy functional group, oxetanyl functional group, or alkenyl ether functional group; the oxygen-containing organic group has a carbonyl group or ether bond.

[22-1] The method of producing a cured organopolysiloxane resin film having gas barrier properties according to [22], characterized in that the acrylic functional group is an acryloxy functional group or acrylamide functional group.

[23] The method of producing a cured organopolysiloxane resin film having gas barrier properties according to [22], characterized in that the acrylic functional group is an acryloxyalkyl group, methacryloxyalkyl group, acrylamidealkyl group or methacrylamidealkyl group; the epoxy functional group is a glycidoxyalkyl group or epoxycyclohexylalkyl group; and the alkenyl ether functional group is a vinyloxyalkyl group; and the oxygen-containing organic group has a carboxylic acid ester bond, carboxylic acid amide bond or ether bond.

[24] The method of producing a cured organopolysiloxane resin film having gas barrier properties according to [19] or [20], characterized in that the silicon oxynitride layer is formed by a reactive ion plating procedure.”.

The aforementioned object is also achieved by

“[25] A cured organopolysiloxane resin film having gas barrier properties characterized in that a hydrosilyl group- or silanol-containing cured organopolysiloxane layer is formed on a film which is transparent in the visible region and comprises a cured organopolysiloxane resin obtained by a crosslinking reaction between
(A) organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyl per molecule and
(B) an organosilicon compound having at least two silicon-bonded hydrogen atoms per molecule
   in the presence of
(C) a hydrosilylation reaction catalyst,
   and a transparent inorganic layer selected from the group consisting of a silicon oxynitride layer, silicon nitride layer, and silicon oxide layer is formed on the cured organopolysiloxane layer.

[26] The cured organopolysiloxane resin film having gas barrier properties according to [25], characterized in that the organopolysiloxane resin represented by the average siloxane unit formula (1) is composed of at least one siloxane unit represented by formula [X_{(3-b)}R¹_{b}SiO_{1/2}] (in the formula, X is C₂ to C₁₀ monovalent unsaturated aliphatic hydrocarbyl, R¹ is C_{1 to} C₁₀ monovalent hydrocarbyl other than X, and b is 0, 1, or 2) and at least one siloxane unit represented by formula [R²SiO_{3/2}] (in the formula, R² is C₁ to C₁₀ monovalent hydrocarbyl other than X), or at least one siloxane unit represented by formula [X_{(3-b)}R¹_{b}SiO_{1/2}](in the formula, X is C_{2 to} C₁₀ monovalent unsaturated aliphatic hydrocarbyl, R¹ is C_{1 to} C₁₀ monovalent hydrocarbyl other than X, and b is 0, 1, or 2), at least one siloxane unit represented by formula [R²SiO_{3/2}] (in the formula, R² is C₁ to C₁₀ monovalent hydrocarbyl other than X), and at least one siloxane unit represented by formula [SiO_{4/2}].

[27] The cured organopolysiloxane resin film having gas barrier properties according to [26], characterized in that the organopolysiloxane resin is represented by the average siloxane unit formula

[X_{(3-b)}R¹_{b}SiO_{1/2}]ᵥ[R²SiO_{3/2}]_{w} (2)

(in the formula, X, R¹, R², and b are defined as in [26], 0.8<w<1.0, and v+w=1) or by the average siloxane unit formula

[X_{(3-b)}R¹_{b}SiO_{1/2}]ₓ[R²SiO_{3/2}]_{y}[SiO_{4/2}]_{z} (3)

(in the formula, X, R¹, R², and b are defined as in [26], 0<x<0.4, 0.5<y<1, 0<z<0.4, and x+y+z=1).”.

The aforementioned object is also achieved by

“[28] A method of producing the cured organopolysiloxane resin film having gas barrier properties according to [25], said method being characterized by

coating and curing a hydrosilylation reaction-curable organopolysiloxane composition comprising
(a) an organopolysiloxane that has at least two alkenyl groups per molecule,
(b) an organosilicon compound that has at least two silicon-bonded hydrogen atoms per molecule, and
(c) a hydrosilylation reaction catalyst
wherein the molar ratio between the hydrosilyl groups in component (b) and the alkenyl groups in component (a) is at least 1.05,
   on a film which is transparent in the visible region and comprises a cured organopolysiloxane resin obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst,
   to form a hydrosilyl group-containing cured organopolysiloxane layer on said film; and
forming, by vapor deposition, a transparent inorganic layer selected from the group consisting of a silicon oxynitride layer, silicon nitride layer, and silicon oxide layer, on the cured organopolysiloxane layer.

[29] A method of producing the cured organopolysiloxane resin film having gas barrier properties according to [25], said method being characterized by

coating and curing a condensation reaction-curable organosilane, condensation reaction-curable organosilane composition, condensation reaction-curable organopolysiloxane, or condensation reaction-curable organopolysiloxane composition on a film which is transparent in the visible region and comprises a cured organopolysiloxane resin obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst,
   to form a silanol group-containing cured organopolysiloxane layer on said film; and

forming, by vapor deposition, a transparent inorganic layer selected from the group consisting of a silicon oxynitride layer, silicon nitride layer, and silicon oxide layer, on the cured organopolysiloxane layer.

[30] The method of producing a cured organopolysiloxane resin film having gas barrier properties according to [28] or [29], characterized in that the silicon oxynitride layer is formed by a reactive ion plating procedure.

[31] A method of producing a cured organopolysiloxane resin film having gas barrier properties, said method being characterized by

forming a silicon oxynitride layer by a reactive ion plating procedure on a hydrosilyl group-containing cured organopolysiloxane resin film which is transparent in the visible region and is obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
(wherein the molar ratio between the hydrosilyl groups in component (B) and the unsaturated aliphatic hydrocarbyl in component (A) is 1.05 to 1.50)
   in the presence of
      (C) a hydrosilylation reaction catalyst.”.

### Effects of the Invention

Because its transparent inorganic layer, that is, transparent inorganic film selected from the group consisting of a silicon oxynitride layer, that is, silicon oxynitride film, silicon nitride layer, that is, silicon nitride film, and silicon oxide layer, that is, silicon oxide film is formed on the visible region-transparent cured organopolysiloxane resin film through an interposed layer of cured organopolysiloxane that has organic functional groups, organic groups produced by polymerization between polymerizable organic functional groups, or hydrosilyl groups or silanol groups, the present invention's cured organopolysiloxane resin film, particularly free-standing film having gas barrier properties has a transparent inorganic film layer that is uniformly formed and that exhibits an excellent adhesiveness with the resin film, thereby yielding excellent gas barrier properties. The cured organopolysiloxane resin film, particularly free-standing film having gas barrier properties of the present invention exhibits an excellent durability and an excellent capacity to block a variety of gases, such as air, steam, nitrogen gas, oxygen gas, carbon dioxide gas, argon gas, and so forth. The methods of producing the cured organopolysiloxane resin film, particularly free-standing film of the present invention provide the aforementioned cured organopolysiloxane resin film, particularly free-standing film easily and surely.

### BRIEF DESCRIPTION OF THE DRAWING

FIG. 1 is a cross-sectional diagram of a cured organopolysiloxane resin film having gas barrier properties in which an organic functional group-containing cured organopolysiloxane layer is formed on a cured organopolysiloxane resin film and a silicon oxynitride layer is formed on the cured organopolysiloxane layer.

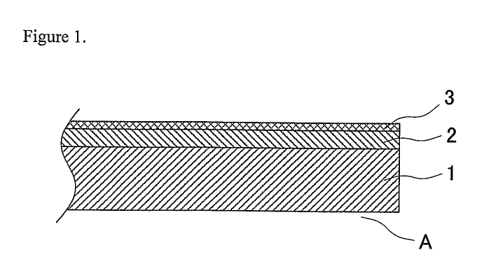

### MODE FOR CARRYING OUT THE INVENTION

The cured organopolysiloxane resin films, particularly free-standing films having gas barrier properties of the first, second, and third embodiments of the present invention are characterized in that a layer of a cured organopolysiloxane that contains organic functional groups, or organic groups produced by polymerization between or among polymerizable organic functional groups, or hydrosilyl groups or silanol groups, is formed on a film which is transparent in the visible region and comprises a cured organopolysiloxane resin obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst,
   and in that a transparent inorganic layer selected from the group consisting of a silicon oxynitride layer, silicon nitride layer, and silicon oxide layer is formed on the cured organopolysiloxane layer.

The visible region-transparent film comprising a cured organopolysiloxane resin yielded by a crosslinking reaction between component (A) and component (B) in the presence of component (C) is in particular a free-standing film. This is a film that exists in a free-standing state and is not a film coated on a substrate such as a glass substrate, metal substrate, or ceramic substrate. The formation of the transparent inorganic layer selected from the group consisting of a silicon oxynitride layer, silicon nitride layer, and silicon oxide layer is superfluous when the cured organopolysiloxane resin film layer is formed on a gas barrier material such as glass, metal, or ceramic.

Under the action of component (C), component (A) undergoes crosslinking and curing through an addition reaction between its unsaturated aliphatic hydrocarbyl and the silicon-bonded hydrogen atom, that is, hydrosilyl group in component (B).

R in average siloxane unit formula (1) is C_{1 to} C₁₀ monovalent hydrocarbyl and is bonded to the silicon atom in the organopolysiloxane. This C_{1 to} C₁₀ monovalent hydrocarbyl can be exemplified by alkyl such as methyl, ethyl, n-propyl, isopropyl, n-butyl, isobutyl, sec-butyl, tert-butyl, hexyl, octyl, and so forth; aryl such as phenyl, tolyl, xylyl, and so forth; aralkyl such as benzyl, phenylethyl, and so forth; and C_{2 to} C₁₀ unsaturated aliphatic hydrocarbyl such as vinyl, 1-propenyl, allyl, isopropenyl, 1-butenyl, 2-butenyl, 1-hexenyl, and so forth, and is particularly exemplified by alkenyl.

An average of at least 1.2 C_{2 to} C₁₀ unsaturated aliphatic hydrocarbyls are present per molecule in component (A). Viewed from the perspective of curability, preferably an average of at least 1.5 and more preferably an average of at least 2.0 C_{2 to} C₁₀ unsaturated aliphatic hydrocarbyls are present per molecule.

When component (B) is an organosilicon compound that contains two silicon-bonded hydrogen atoms per molecule, component (A) must comprise a molecule that has at least three C_{2 to} C₁₀ unsaturated aliphatic hydrocarbyls per molecule in order for it to cure by the addition reaction with component (B).

When component (A) contains two C_{2 to} C₁₀ unsaturated aliphatic hydrocarbyls per molecule, component (B) must comprise a molecule that has at least three silicon-bonded hydrogen atoms per molecule in order for component (A) to cure by the addition reaction with component (B).

While component (A) must be mainly organopolysiloxane resin that contains at least three C_{2 to} C₁₀ unsaturated aliphatic hydrocarbyls per molecule or organopolysiloxane resin that contains at least two C_{2 to} C₁₀ unsaturated aliphatic hydrocarbyls per molecule, component (A) may contain organopolysiloxane resin that contains one C_{2 to} C₁₀ unsaturated aliphatic hydrocarbyl per molecule.

a in the average siloxane unit formula (1) is a number with an average value in the range 0.5<a<2. a denotes the average number of R′ s per silicon atom in the organopolysiloxane resin. When the average a=2 in the average siloxane unit formula (1), the organopolysiloxane is a diorganopolysiloxane, and, because this is straight chain or cyclic, a is smaller than an average of 2. The degree of branching in the organopolysiloxane resin molecule increases as a declines from an average of 2; however, a is preferably less than or equal to an average of 1.7 in order to fall into the organopolysiloxane resin category. a is greater than an average of 0.5; however, it is preferably greater than or equal to an average of 1.0 due to the substantial inorganic character at less than an average of 1.

Viewed from the perspective of the properties of the cured product, the organopolysiloxane resin represented by the average siloxane unit formula (1) is preferably composed of at least one siloxane unit represented by formula [X_{(3-b)}R_{b}SiO_{1/2}] (in the formula, X is C_{2 to} C₁₀ monovalent unsaturated aliphatic hydrocarbyl, R¹ is C_{1 to} C₁₀ monovalent hydrocarbyl other than X, and b is 0, 1, or 2) and at least one siloxane unit represented by formula [R²SiO_{3/2}] (in the formula, R² is C₁ to C₁₀ monovalent hydrocarbyl other than X), or at least one siloxane unit represented by formula [X_{(3-b)}R¹_{b}SiO_{1/2}] (in the formula, X is C_{2 to} C₁₀ monovalent unsaturated aliphatic hydrocarbyl, R¹ is C_{1 to} C₁₀ monovalent hydrocarbyl other than X, and b is 0, 1, or 2), at least one siloxane unit represented by formula [R²SiO_{3/2}] (in the formula, R² is C_{1 to} C₁₀ monovalent hydrocarbyl other than X), and at least one siloxane unit represented by formula [SiO_{4/2}].

Viewed from the perspective of the characteristics of the cured product and particularly the heat resistance, the organopolysiloxane resin represented by the average siloxane unit formula (1) is preferably represented by the average siloxane unit formula

[X_{(3-b)}R¹_{b}SiO_{1/2}]ᵥ[R²SiO_{3/2}]_{w} (2)

(in the formula, X, R¹, R², and b are defined as above, 0.80≦w<1.0, and v+w=1) or by the average siloxane unit formula

[X_{(3-b)}R¹_{b}SiO_{1/2}]ₓ[R²SiO_{3/2}]_{y}[SiO_{4/2}]_{z} (3)

(in the formula, X, R¹, R², and b are defined as above, 0<x<0.4, 0.5<y<1, 0<z<0.4, and x+y+z=1). Two or more of these organopolysiloxane resins may be used in combination.

X is C_{2 to} C₁₀ monovalent unsaturated aliphatic hydrocarbyl, and examples thereof are alkenyl groups such as vinyl, 1-propenyl, allyl, isopropenyl, 1-butenyl, 2-butenyl, 1-hexenyl, and so forth; vinyl is preferred based on considerations of the ease of production and the hydrosilylation reactivity.

R¹ and R² are C_{1 to} C₁₀ monovalent hydrocarbyl other than X and are the R groups defined above from which X is excluded. R¹ and R² can be exemplified by alkyl such as methyl, ethyl, n-propyl, isopropyl, n-butyl, isobutyl, sec-butyl, tert-butyl, hexyl, octyl, and so forth; aryl such as phenyl, tolyl, xylyl, and so forth; and aralkyl such as benzyl, phenylethyl, and so forth; wherein methyl and phenyl are preferred from the perspective of the heat resistance and ease of production of the organopolysiloxane resin. At least 50 mole % of the total monovalent hydrocarbyl in the molecule is preferably phenyl based on a consideration of the thermal properties of the cured organopolysiloxane resin.

The [X_{(3-b)}R¹_{b}SiO_{1/2}] unit in the average siloxane unit formula (2) and the average siloxane unit formula (3) is exemplified by Me₂ViSiO_{1/2}, MePhViSiO_{1/2}, and MeVi₂SiO_{1/2}, and the R²SiO_{3/2} unit in the average siloxane unit formula (2) and the average siloxane unit formula (3) is exemplified by MeSiO_{3/2} and PhSiO_{3/2} wherein Me is methyl group; Ph is phenyl group, and Vi is vinyl group; this also applies hereafter.

The organopolysiloxane resin represented by the average siloxane unit formula (1) can additionally contain the R₂SiO_{2/2} unit, wherein this R₂SiO_{2/2} unit is exemplified by Me₂SiO_{2/2}, MeViSiO_{2/2}, and MePhSiO_{2/2}.

The organosilicon compound having at least two silicon-bonded hydrogen atoms per molecule that is component (B) brings about crosslinking and curing through its addition reaction, under the action of component (C), with the silicon-bonded unsaturated aliphatic hydrocarbyls, particularly alkenyls in component (A).

Component (B) may be any of silylated hydrocarbon, organosilane, organosiloxane oligomer, organopolysiloxane, and so forth. In each instance these contain at least two silicon-bonded hydrogen atoms per molecule, while the organosiloxane oligomer and organopolysiloxane preferably contain an average of at least two silicon-bonded hydrogen atoms per molecule.

The molecular structure here is not particularly limited; however, in order to produce a high-strength cured product, at least 5 mole % of the total silicon-bonded groups is aromatic hydrocarbyl and more preferably at least 10 mole % is aromatic hydrocarbyl. The properties and thermal characteristics of the cured product are unsatisfactory at less than 5 mole %.

Phenyl, tolyl, and xylyl are examples of the monovalent aromatic hydrocarbyl wherein phenyl is preferred. The aromatic hydrocarbyl may be a divalent aromatic hydrocarbyl, for example, phenylene. The alkyl described above is preferred for the organic groups other than the monovalent aromatic hydrocarbyl, wherein methyl is more preferred.

Component (B) is specifically exemplified by the following: silylated hydrocarbon and organosilane containing two silicon-bonded hydrogens, e.g., diphenyldihydrogensilane, 1,3-bis(dimethylhydrogensilyl)benzene, 1,4-bis(dimethylhydrogensilyl)benzene, and so forth; organosiloxane oligomers as represented by the formulas (HMePhSi)₂O, (HMe₂SiO)₂SiPh₂, (HMePhSiO)₂SiPh₂, (HMe₂SiO)₂SiMePh, (HMe₂SiO)(SiPh₂)(OSiMe₂H), (HMe₂SiO)₃SiPh, and (HMePhSiO)₃SiPh; organopolysiloxane resin comprising (PhSiO_{3/2}) units and (Me₂HSiO_{1/2}) units; organopolysiloxane resin comprising (PhSiO_{3/2}) units, (Me₂SiO_{2/2}) units, and (Me₂HSiO_{1/2}) units; organopolysiloxane resin comprising (PhSiO_{3/2}) units, (MeSiO_{3/2}) units, and (MeHSiO_{1/2}) units; organopolysiloxane resin comprising (PhSiO_{3/2}) units and (MeHSiO_{2/2}) units; and organopolysiloxane comprising (Me₂HSiO_{1/2}) units, (MePh₂SiO_{1/2}) units, and (SiO_{4/2}) units.

Additional examples are straight-chain organopolysiloxane comprising (MePhSiO_{2/2}) units and (Me₂HSiO_{1/2}) units; straight-chain organopolysiloxane comprising (Me₂SiO_{2/2}) units, (MePhSiO_{2/2}) units, and (Me₂HSiO_{1/2}) units; straight-chain organopolysiloxane comprising (MePhSiO_{2/2}) units, (MeHSiO_{2/2}) units, and (Me₃SiO_{1/2}) units; straight-chain organopolysiloxane comprising (MePhSiO_{2/2}) units, (MeHSiO_{2/2}) units, and (Me₂HSiO_{1/2}) units; straight-chain organopolysiloxane comprising (PhHSiO_{2/2}) units and (Me₃SiO_{1/2}) units; straight-chain organopolysiloxane comprising (MeHSiO_{2/2}) units and (MePh₂SiO_{1/2}) units; and cyclic organopolysiloxane comprising only (PhHSiO_{2/2}) units.

Two or more of these organosilicon compounds may be used in combination. Methods for the production of these organosilicon compounds are already publicly known or are commonly known. For example, production can be carried out by the hydrolysis and condensation reaction of SiH-containing organochlorosilane alone or by the cohydrolysis and condensation reaction of SiH-containing organochlorosilane and SiH-free organochlorosilane.

The hydrosilylation reaction catalyst that is component (C) is preferably a metal from Group 8 of the Periodic Table or a compound of such a metal, among which platinum and platinum compounds are preferred. Examples here are microparticulate platinum, chloroplatinic acid, platinum/diolefin complexes, platinum/ketone complexes, platinum/divinyltetramethyldisiloxane complexes, and platinum/phosphine complexes. The hydrosilylation reaction catalyst content is preferably in the range of 0.05 ppm to 300 ppm and more preferably in the range of 0.1 ppm to 50 ppm, in each case as the weight of the metal with reference to the total weight of components (A) and (B). The crosslinking reaction does not develop adequately at below this range, while exceeding this range is not only pointless, but the optical properties may be impaired by the residual metal.

In order to inhibit the hydrosilylation and crosslinking reactions at ambient temperature and thereby lengthen the use time, a hydrosilylation reaction retarder is preferably incorporated in addition to the aforementioned components (A), (B), and (C). Specific examples in this regard are 2-methyl-3-butyn-2-ol, 3,5-dimethyl-1-hexyn-3-ol, 1-ethynyl-1-cyclohexanol, phenylbutynol, and other alkinyl alcohols; 3-methyl-3-penten-1-yne, 3,5-dimethyl-3-hexene-1-yne, and other ene-yne compound; methyl(tris(1,1-dimethyl-2-propinyloxy)) silane, dimethyl(bis(1,1-dimethyl-2-propinyloxy)) silane, and other alkinylsilanes; dimethyl maleate, diethyl fumarate, bis(2-methoxy-1-methylethyl) maleate, and other unsaturated carboxylic acid esters; N,N,N′,N′-tetramethylethylenediamine, ethylenediamine, and other organic amine compounds; diphenylphosphine, diphenylphosphite, trioctylphosphine, diethylphenylphosphonite, and methyldiphenylphosphinite, and other organic phosphine compounds or organic phosphinite compounds. The hydrosilylation reaction retarder content is preferably an amount that provides a value of 1 to 10,000 for the weight ratio versus the aforementioned hydrosilylation reaction catalyst.

In order to impart desired properties to the film comprising the cured organopolysiloxane resin and particularly the free-standing film comprising the cured organopolysiloxane resin, the curable organopolysiloxane resin composition comprising components (A), (B), and (C) may incorporate, in addition to the essential components cited above and insofar as the object of the present invention is not impaired, the various additives typically incorporated into curable organopolysiloxane resin compositions. For example, when a high optical transparency is not required of the film comprising the cured organopolysiloxane resin and particularly the free-standing film comprising the cured organopolysiloxane resin, inorganic micropowder that is a typical filler, for example, a reinforcing silica filler exemplified by fumed silica, colloidal silica, alumina, and so forth, may be incorporated in order thereby to increase the strength of the film comprising the cured organopolysiloxane resin and particularly the free-standing film comprising the cured organopolysiloxane resin. The inorganic powder content will vary with the purpose and the service and can be determined by simple blending tests.

Moreover, even when an inorganic powder is incorporated, the transparency of the cured organopolysiloxane resin film can be preserved by adjusting the particle size of the powder. Since opacification due to particle addition is caused by the light scattering induced by the added particles, scattering can be prevented and the transparency of the cured organopolysiloxane resin film can thereby be preserved when the particle diameter is no more than roughly one-fifth to one-sixth the wavelength of the incident light (corresponding to 80 to 60 nm for the visible region), although this also varies with the refractive index of the material making up the particles. Secondary aggregation of the particles is also a major factor in causing light scattering, and particles that have been subjected to a surface treatment may therefore be incorporated in order to inhibit secondary aggregation.

The curable organopolysiloxane resin composition used to produce the film, articularly free-standing film, of the present invention comprising cured organopolysiloxane resin, may also incorporate a dye or pigment, e.g., a phthalocyanine-type dye, a fluorescent dye, a fluorescent pigment, and so forth. In particular, since the cured organopolysiloxane resin film, particularly free-standing film of the present invention does not exhibit a specific absorption band in the visible region, functionalization then becomes possible through the incorporation of an additive that manifests a prescribed functionality by means of photoexcitation through the absorption of visible light.

The cured organopolysiloxane resin film, particularly free-standing film of the present invention can be produced by the following steps: coating the hereinabove-described curable organopolysiloxane resin composition on a substrate to form an uncured film; crosslinking this uncured film to obtain the cured organopolysiloxane resin film; and thereafter pealing the cured organopolysiloxane resin film from the substrate.

When components (A), (B), and (C) are mixed, the hydrosilylation reaction can proceed even at ambient temperature, resulting in gelation and crosslinking and curing, and for this reason the suitable incorporation of a hydrosilylation reaction retarder as described above is preferred. When component (A) or component (B) is not a liquid at ambient temperature or is a liquid but a high viscosity liquid, dissolution in a suitable organic solvent is preferably done in advance. This organic solvent should have a boiling point no greater than 200° C. given that the temperature during crosslinking can also reach to about 200° C., and should dissolve the component (A) or (B) and should not inhibit the hydrosilylation reaction, but is not otherwise particularly limited.

Examples of preferred organic solvents are ketones such as acetone, methyl isobutyl ketone, and so forth; aromatic hydrocarbons such as toluene, xylene, and so forth; aliphatic hydrocarbons such as heptane, hexane, octane, and so forth; halogenated hydrocarbons such as dichloromethane, chloroform, methylene chloride, 1,1,1-trichloroethane, and so forth; ethers such as THF and so forth; as well as dimethylformamide and N-methylpyrrolidone. The use amount for the organic solvent is, for example, in the range of 1 weight part to 300 weight parts per 100 weight parts of the total of components (A), (B), and (C), but is not limited to this range.

An uncured film is first formed by coating a substrate with a mixture of components (A), (B), and (C), or with a mixture of components (A), (B), and (C) and a hydrosilylation reaction retarder, or with an organic solvent solution of these mixtures. Viewed from the perspective of coatability, the viscosity of the mixture here is preferably no greater than 1×10³Pa·s and more preferably is no greater than 1×10² Pa·s.

The substrate used here should have a smooth, flat surface and should enable peeling of the cured organopolysiloxane resin film, but is not otherwise particularly limited. It is preferably stable with respect to component (A), component (B), component (C), the hydrosilylation reaction retarder, and the organic solvent, and preferably has the ability to withstand the temperature environment during the crosslinking reaction of the uncured film. Examples of preferred substrate materials are inorganic materials such as glass, quartz, ceramics, graphite, and so forth; metals such as steel, stainless steel, alumite, duralumin, and so forth; and polymer materials that are insoluble in the organic solvent and also stable at the boiling point of the organic solvent, e.g., polytetrafluoroethylene and polyethylene terephthalate.

Crosslinking, that is, curing of the uncured film is carried out by standing at room temperature or by heating to a temperature higher than room temperature. When the uncured film contains an organic solvent, the organic solvent is preferably first evaporated off in advance by drying in an air current or by holding at a temperature a little above room temperature. The heating temperature for crosslinking, that is, curing is, for example, from 40° C. (inclusive) to 200° C. (inclusive). The heating regime can be suitably adjusted as necessary. For example, heating for a short period of time can be repeated a plurality of times or heating may be carried out continuously under a single set of conditions for a longer period of time.

The cured organopolysiloxane resin layer formed on the substrate by crosslinking yields a free-standing cured organopolysiloxane resin film upon peeling from the substrate. The peeling means may be a peeling means commonly known in the pertinent technical field, for example, a mechanical peeling means such as a doctor blade or vacuum suction. The thickness of the cured organopolysiloxane resin film, particularly free-standing film may vary as appropriate in conformity with the application and may be 5 to 300 μm thickness typical of polymer films or may be thicker than this.

The cured organopolysiloxane resin film produced in this manner is a free-standing film. It is not a film coated on a substrate, such as a glass, metal, or ceramic substrate, and exists in a free-standing or independent state. Free-standing films are also known as self-supporting films and unsupported films.

This cured organopolysiloxane resin film, particularly free-standing film do not have a specific light absorption band in the visible region and have a light transmittance of at least 85% at 400 nm and provide a light transmittance of at least 88% in the 500 to 700 nm wavelength range. Because this cured organopolysiloxane resin film, particularly free-standing film are not produced by the application of stress to a melt, they are free of the problem of molecular chain orientation. Accordingly, the birefringence is so small that it can be neglected.

This cured organopolysiloxane resin film, particularly free-standing film are obtained by a hydrosilylation reaction-based crosslinking reaction between the unsaturated aliphatic hydrocarbyl groups in component (A) and the silicon-bonded hydrogen atoms in component (B). Because crosslinking by this hydrosilylation reaction is not accompanied by the evolution of low molecular weight by-products, the volumetric shrinkage of the film that accompanies crosslinking is held down to low levels in comparison to the condensation-type crosslinking reaction encountered in the usual thermosetting resins. As a consequence, there is also little internal stress in the film, particularly free-standing film comprising the cured organopolysiloxane resin yielded by the hydrosilylation crosslinking reaction. The generation of internal stress-induced strain is therefore inhibited. This also desirably contributes to an improved optical uniformity of the film and an improved film strength.

Even when heated to 300° C., this cured organopolysiloxane resin film, particularly free-standing film keep their film shape and also do not exhibit weight change. Moreover, they also exhibit excellent mechanical properties after heating and exhibit almost no change in mechanical properties by the heating.

Accordingly, this cured organopolysiloxane resin film, particularly free-standing film have the high heat resistance typical of general-purpose engineering plastics, such as polycarbonates, and as a consequence are well suited for application as a substrate or base for gas barrier films where exposure to high temperatures occurs during formation of a transparent inorganic layer.

The cured organopolysiloxane resin film having gas barrier properties of the first embodiment of the present invention is characterized in that an organic functional group-containing cured organopolysiloxane layer is formed on a film which is transparent in the visible region and comprises the cured organopolysiloxane resin obtained by a crosslinking reaction between
(A) an organopolysiloxane resin that is represented by the average siloxane unit formula

RₐSiO_{(4-a)/2} (1)
(in the formula, R is C₁ to C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst,
   and a transparent inorganic layer selected from the group consisting of a silicon oxynitride layer, silicon nitride layer, and silicon oxide layer is formed on the cured organopolysiloxane layer.

The organic functional groups are bonded to a portion or all of the silicon atoms in the organopolysiloxane constituting the cured organopolysiloxane layer. The organic functional group-containing cured organopolysiloxane layer may contain a small amount of silanol groups, hydrosilyl groups, and/or silicon atom-bonded hydrolysable groups which are originated in curable organosilanes or curable organopolysiloxanes for forming the organic functional group-containing cured organopolysiloxane layer.

Viewed from the standpoint of adhesion of the transparent inorganic layer selected from the group consisting of the silicon oxynitride layer, silicon nitride layer, and silicon oxide layer, the organic functional group is preferably an oxygen-containing organic functional group. The oxygen-containing organic functional group preferably consists of carbon atom, hydrogen atom and oxygen atom, or consists of carbon atom, hydrogen atom, oxygen atom and nitrogen atom. The oxygen-containing organic group preferably contains a carbonyl group, or a polar bond, e.g., a carboxylic acid ester bond, carboxylic acid amide bond, ether bond (C—O—C) and so forth.

When the cured organopolysiloxane layer is formed by a hydrosilylation reaction, the organic functional group which does not inhibit the hydrosilylation reaction is preferable. An acrylic functional group, an epoxy functional group, and an oxetanyl functional group are preferred examples of the organic functional group, specifically oxygen-containing organic functional group.

Other examples are a crotonyl functional group and a cinnamoyl functional group, which can be regarded as types of the acrylic functional group. The acrylic functional group is known as an acryloyl functional group, and its representative example is represented by the formula CH₂═CHCO—.

Preferred acrylic functional groups can be exemplified by an acryloxy functional group and acrylamide functional group;

Preferred acryloxy functional groups can be exemplified by an acryloxyalkyl group represented by CH₂═CHCOOR— (wherein R in the formulas is an alkylene group such as propylene) such as acryloxypropyl group, and by a methacryloxyalkyl group represented by CH₂═CH(CH₃)COOR— (wherein R in the formulas is an alkylene group such as propylene) such as methacryloxypropyl group.
Preferred acrylamide functional groups can be exemplified by a N-alkyl-N-acrylamidealkyl group represented by CH₂═CHCON(R)— (wherein R in the formulas is an alkyl group such as methyl) such as N-alkyl-N-acrylamidepropyl group, and by a N-alkyl-N-methacrylamide group represented by CH₂═C(CH₃)CON(R)— (wherein R in the formulas is an alkyl group such as methyl) such as N-alkyl-N-methacrylamidepropyl group.
The alkylene group here preferably has 2 to 6 carbon atoms.

Preferred specific examples of the epoxy functional group are epoxymethyl group; 2-epoxyethyl group; glycidoxyalkyl groups such as β-glycidoxyethyl group and 3-glycidoxpropyl group; and epoxycyclohexylalkyl groups such as β-(3,4-epoxycyclohexyl)ethyl group and 3-(3,4-epoxycyclohexyl)propyl group. Preferred specific examples of the oxetanyl functional group are 2-oxetanylbutyl group and 3-(2-oxetanylbutyloxy)propyl group.

The aforementioned acrylic functional group can be polymerized by exposure to high-energy radiation or actinic energy radiation, e.g., ultraviolet radiation, electron beam, gamma radiation, and so forth, and it is therefore also a polymerizable organic functional group. Moreover, this acrylic functional group again falls into the category of polymerizable organic functional groups because it can be polymerized by the application of heat. The vinyl ether group, for example, the vinyloxyalkyl group is another organic functional group that exhibits polymerizability. Preferred specific examples of the alkenyl ether functional group are vinyloxyalkyl group, allyloxyalkyl group, and allyloxyphenyl group. This alkenyl has preferably 2 to 6 carbon atoms.

The aforesaid epoxy functional group can undergo ring-opening polymerization upon exposure to ultraviolet radiation in the presence of a photopolymerization initiator and is thus also a polymerizable organic functional group.

The epoxy functional group and the oxetanyl functional group are also polymerizable organic functional groups by virtue of undergoing ring-opening polymerization in the presence of a catalyst such as an aliphatic amine, alicyclic amine, aromatic amine, imidazole, organic dicarboxylic acid, organic dicarboxylic acid anhydride, and so forth.

Examples of other organic functional groups are hydroxyl-containing organic functional groups and oxyalkylene bond-containing organic functional groups.

The hydroxyl-containing organic functional groups are exemplified by hydroxyalkyl groups such as 3-hydroxypropyl. The oxyalkylene bond-containing organic functional groups are exemplified by an alkoxyalkyl group, and a hydroxypoly(alkyleneoxy)alkyl group such as hydroxy(ethyleneoxy)propyl and hydroxypoly(ethyleneoxy)propyl.

Amino-containing organic functional groups can also be used from the standpoint of the adhesiveness of the transparent inorganic layer selected from the group consisting of a silicon oxynitride layer, silicon nitride layer, and silicon oxide layer, and these organic functional groups can be exemplified by 3-aminopropyl, N-(β-aminoethyl)-3-aminopropyl, N-phenylaminopropyl, N-cyclohexylaminopropyl, and N-benzylaminopropyl.

The organic functional group-containing cured organopolysiloxane layer can be formed on the cured organopolysiloxane resin film, particularly free-standing film by coating an organic functional group-containing curable organosilane per se or a composition thereof onto the film and curing said organosilane per se or a composition thereof.

The organic functional group-containing curable organosilane per se or composition thereof is preferably an organic functional group-containing, condensation reaction-curable organosilane per se or a composition thereof, that can cure by a condensation reaction, for example, an alcohol-eliminating condensation reaction between silicon-bonded alkoxy groups.

Formation can also be achieved by coating and curing an organic functional group-containing curable organopolysiloxane per se or a composition thereof.

The organic functional group-containing curable organopolysiloxane per se or composition thereof is preferably an organic functional group-containing, condensation reaction-curable organopolysiloxane per se or a composition thereof, that can cure by a condensation reaction, for example, an alcohol-eliminating condensation reaction between silicon-bonded hydrolyzable groups, for example, silicon-bonded alkoxy groups.

The organic functional group-containing curable organopolysiloxane composition is also preferably an organic functional group-containing, hydrosilylation reaction-curable organopolysiloxane composition that can cure by an addition reaction between silicon-bonded alkenyl groups and hydrosilyl groups.

The organic functional group-containing curable organopolysiloxane should contain at least one organic functional group per molecule, but preferably contains a plurality of organic functional groups per molecule from the standpoint of the adhesiveness of the transparent inorganic layer selected from the silicon oxynitride layer, silicon nitride layer, and silicon oxide layer. The organic functional group may be up to 100 mole % of the total organic groups that are bonded through the C—Si bond in the organic functional group-containing curable organopolysiloxane. For example, this value is 43.4 mole % in Synthesis Example 2 herein after described.

(1) An example of the organic functional group-containing, condensation reaction-curable organosilane is a humidity-curable organosilane that contains one organic functional group and three silicon-bonded hydrolyzable groups.

(2) Examples of the organic functional group-containing, condensation reaction-curable organosilane compositions are a curable composition comprising a condensation reaction catalyst and organosilane that contains one organic functional group and three silicon-bonded hydrolyzable groups and a curable composition comprising a condensation reaction catalyst, organosilane that contains one organic functional group and two silicon-bonded hydrolyzable groups, and organosilane that contains three or four silicon-bonded hydrolyzable groups.

(3) An example of the organic functional group-containing, condensation reaction-curable organopolysiloxane is a humidity-curable organopolysiloxane that contains at least one organic functional group per molecule and at least three silicon-bonded hydrolyzable groups per molecule.

(4) Examples of the organic functional group-containing, condensation reaction-curable organopolysiloxane compositions are a curable composition comprising a condensation reaction catalyst and organopolysiloxane that contains at least one organic functional group per molecule and at least three silicon-bonded hydrolyzable groups per molecule and a curable composition comprising a condensation reaction catalyst, organopolysiloxane that contains at least one organic functional group per molecule and one or two silicon-bonded hydrolyzable groups per molecule, and organopolysiloxane that contains at least three silicon-bonded hydrolyzable groups while lacking the organic functional group.

The organic functional group in the above-cited organic functional group-containing curable organosilane, organic functional group-containing, condensation reaction-curable organosilane composition, organic functional group-containing curable organopolysiloxane, organic functional group-containing, condensation reaction-curable organopolysiloxane, and organic functional group-containing, condensation reaction-curable organopolysiloxane composition is that which has already been described in the preceding.

The condensation-reactive group in the organic functional group-containing, condensation reaction-curable organosilane and the organic functional group-containing, condensation reaction-curable organopolysiloxane is silanol group and a silicon-bonded hydrolyzable group, which can be exemplified by alkoxy, alkenyloxy, acyloxy, ketoxime, and alkylamine, wherein alkoxy is preferred and methoxy and ethoxy are more preferred considering the volatilization behavior of the alcohol produced by their hydrolysis.

The auxiliary use of heating or an hydrolysis/condensation reaction catalyst is necessary in those instances where the silicon-bonded hydrolyzable group does not undergo humidity-induced hydrolysis/condensation or is refractory to hydrolysis/condensation. The hydrolysis/condensation reaction catalyst can be exemplified by tetraalkoxytitanium, alkoxytitanium chelates, tetraalkoxyzirconium, trialkoxyaluminum, organotin compounds; exemplified by dialkyltin dicarboxylate salts and tin salts of a tetracarboxylic acid, and organic amines.

The aforementioned organic functional group-containing, condensation reaction-curable organosilane composition and organic functional group-containing, condensation reaction-curable organopolysiloxane composition may contain a microparticulate reinforcing silica insofar as the optical transmittance of the cured product is not impaired.

A typical example of the organosilane that contains one organic functional group per molecule and three silicon-bonded hydrolyzable groups per molecule is an organic functional group-containing organotrialkoxysilane represented by the formula YR⁴Si(OR⁵)₃ (in the formula, YR⁴ is an organic functional group, R⁴ is C_{1 to} C₆ alkylene, and R⁵ is C₁ to C₆ alkyl). The organic functional group here is the same as that described above. The C_{1 to} C 6 alkylene can be exemplified by ethylene, propylene, butylene, pentylene, and hexylene. R⁵ can be exemplified by methyl, ethyl, propyl, and butyl. C_{1 to} C₆ alkylene means alkylene group having one to six carbon atoms, and C₁ to C₆ alkyl means alkyl group having one to six carbon atoms.

The following are specific examples of the organic functional group-containing organotrialkoxysilane:
3-acryloxypropyltrimethoxysilane,
3-methacryloxypropyltrimethoxysilane,
3-methacryloxypropyltriethoxysilane,
3-glycidoxypropyltrimethoxysilane,
3-glycidoxypropyltriethoxysilane,
2-(3,4-epoxycyclohexyl)ethyltrimethoxysilane,
2-(3,4-epoxycyclohexyl)ethyltriethoxysilane,
3-hydroxypropyltriethoxysilane,
3-aminopropyltrimethoxysilane,
3-aminopropyltriethoxysilane,
3-phenylaminopropyltrimethoxysilane,
3-cyclohexylaminopropyltrimethoxysilane,
3-(2-aminoethylamino)propyltrimethoxysilane, and
3-benzylaminopropyltrimethoxysilane.

Typical examples of the organosilane that contains one organic functional group per molecule and one or two silicon-bonded hydrolyzable groups per molecule are an organic functional group-containing organodialkoxysilane represented by the formula YR⁴SiR⁶(OR⁵)₂ and an organic functional group-containing organomonoalkoxysilane represented by the formula YR⁴Si(R⁶)₂(OR⁵) (in the formulas, YR⁴ is an organic functional group, R⁴ is C_{1 to} C₆ alkylene, R⁵ is C_{1 to} C₆ alkyl, and R⁶ is C₁ to C₆ alkyl or phenyl group).

Specific examples thereof are as follows:
3-methacryloxypropylmethyldimethoxysilane,
3-methacryloxypropylmethyldiethoxysilane,
3-methacryloxypropyldimethylmethoxysilane,
3-glycidoxypropylmethyldimethoxysilane,
3-glycidoxypropylmethyldiethoxysilane,
3-glycidoxypropyldimethylmethoxysilane,
2-(3,4-epoxycyclohexyl)ethylmethyldimethoxysilane,
2-(3,4-epoxycyclohexyl)ethylmethyldiethoxysilane,
3-aminopropylmethyldimethoxysilane, and
3-(2-aminoethylamino)propylmethyldiethoxysilane.

A typical example of the organic functional group-free organosilane that contains three silicon-bonded hydrolyzable groups per molecule is an organotrialkoxysilane represented by the formula R⁷Si(OR⁵)₃ (in the formula, R⁷ is C_{1 to} C₆ alkyl, C_{2 to} C₆ alkenyl, or phenyl group, and R⁵ is C_{1 to} C₆ alkyl). C_{2 to} C₆ alkenyl means alkenyl group having two to six carbon atoms.

Specific examples are alkyltrialkoxysilanes exemplified by methyltrimethoxysilane, methyltriethoxysilane, methyltripropoxysilane, ethyltrimethoxysilane, and ethyltripropoxysilane, phenyltrialkoxysilanes exemplified by phenyltrimethoxysilane and phenyltriethoxysilane, and vinyltrialkoxysilanes exemplified by vinyltrimethoxysilane and vinyltriethoxysilane.

The organic functional group-free organosilane that contains four silicon-bonded hydrolyzable groups in each molecule is exemplified by tetraalkoxysilane such as tetraethoxysilane and tetrapropoxysilane.

The organopolysiloxane that contains at least one organic functional group per molecule and at least three silicon-bonded hydrolyzable groups per molecule can be exemplified by the partial hydrolysis and condensation product from an organic functional group-containing organotrialkoxysilane represented by the formula YR⁴Si(OR⁵)₃ (in the formula, YR⁴ is an organic functional group, R⁴ is C_{1 to} C₆ alkylene, and R⁵ is C_{1 to} C₆ alkyl) and by the partial condensation reaction product which retains four silicon-bonded alkoxy groups of the organic functional group-containing organotrialkoxysilane represented by the formula YR⁴Si(OR⁵)₃ and a silanol-endblocked dimethylpolysiloxane of which degree of polymerization is 2 to 50.

An example of the organopolysiloxane that has at least one organic functional group per molecule and one or two silicon-bonded hydrolyzable groups per molecule is the partial condensation reaction product retaining two silicon-bonded alkoxy groups of an organic functional group-containing organodialkoxysilane represented by the formula YR⁴SiR⁶(OR⁵)₂ (in the formula, YR⁴ is an organic functional group, R⁴ is C_{1 to} C₆ alkylene, R⁵ is C_{1 to} C₆ alkyl, and R⁶ is C_{1 to} C₆ alkyl or phenyl group) and a silanol-endblocked dimethylpolysiloxane of which degree of polymerization is 2 to 50.

Examples of the organic functional group-free organopolysiloxane that contains at least three silicon-bonded hydrolyzable groups per molecule are the partial hydrolysis and condensation product of a hydrophobic organotrialkoxysilane represented by the formula R⁷Si(OR⁵)₃ (in the formula, R⁷ is C_{1 to} C₆ alkyl, C_{2 to} C₆ alkenyl, or phenyl group, and R⁵ is C₁ to C₆ alkyl) and the partial condensation reaction product which retains four silicon-bonded alkoxy groups of a hydrophobic organotrialkoxysilane represented by the formula R⁷Si(OR⁵)₃ and a silanol-endblocked dimethylpolysiloxane of which degree of polymerization is 2 to 50.

The aforementioned organic functional group-containing, condensation reaction-curable organosilane per se or composition thereof, or the aforementioned organic functional group-containing, condensation reaction-curable organopolysiloxane per se or composition thereof, can be coated on the cured organopolysiloxane resin film and can be cured by heating or by standing at ambient temperature. The auxiliary use of heating as described above or an hydrolysis/condensation reaction catalyst is necessary in those instances where humidity-induced hydrolysis/condensation does not occur or hydrolysis/condensation proceeds with difficulty.

The organic functional group-containing, hydrosilylation reaction-curable organopolysiloxane composition can be exemplified by the following:

(1) a composition comprising an organopolysiloxane that contains at least one organic functional group per molecule and at least two silicon-bonded alkenyl groups per molecule, an organosilane that lacks the organic functional group and that contains at least two silicon-bonded hydrogen atoms per molecule excluding, however, the combination of an organopolysiloxane that contains two silicon-bonded alkenyl groups with an organosilane that contains two silicon-bonded hydrogen atoms, and a hydrosilylation reaction catalyst, and

(2) a composition comprising an organopolysiloxane that contains at least one organic functional group per molecule and at least two silicon-bonded alkenyl groups per molecule, an organopolysiloxane that lacks the organic functional group and that contains at least two silicon-bonded hydrogen atoms per molecule excluding, however, the combination of an organopolysiloxane that contains two silicon-bonded alkenyl groups with an organopolysiloxane that contains two silicon-bonded hydrogen atoms, and a hydrosilylation reaction catalyst.

Additional examples are as follows:

(3) a composition comprising an organopolysiloxane that lacks the organic functional group and that contains at least two silicon-bonded alkenyl groups per molecule, an organopolysiloxane that contains at least one organic functional group per molecule and at least two silicon-bonded hydrogen atoms per molecule excluding, however, the combination of an organopolysiloxane that contains two silicon-bonded alkenyl groups with an organopolysiloxane that contains two silicon-bonded hydrogen atoms, and a hydrosilylation reaction catalyst, and

(4) a composition comprising an organopolysiloxane that contains at least one organic functional group per molecule and at least two silicon-bonded alkenyl groups per molecule, an organopolysiloxane that contains at least one organic functional group per molecule and at least two silicon-bonded hydrogen atoms per molecule (excluding, however, the combination of an organopolysiloxane that contains two silicon-bonded alkenyl groups with an organopolysiloxane that contains two silicon-bonded hydrogen atoms), and a hydrosilylation reaction catalyst.

The organic functional groups in the aforementioned organic functional group-containing organopolysiloxane and organic functional group-containing organosilane are as described above.

The alkenyl in the aforementioned organopolysiloxanes can be exemplified by vinyl, allyl, butenyl, pentenyl, and hexenyl with vinyl being preferred.

Specific examples of the organopolysiloxane that contains at least one organic functional group per molecule and at least two silicon-bonded alkenyl groups per molecule are as follows:
dimethylsiloxane-methyl(3-methacryloxypropyl)siloxane copolymer endblocked at both terminals by dimethylvinylsiloxy groups,
dimethylsiloxane-methylvinylsiloxane copolymer endblocked at both terminals by dimethyl(3-methacryloxypropyl)siloxy groups,
dimethylsiloxane-methyl(3-glycidoxypropyl)siloxane copolymer endblocked at both terminals by dimethylvinylsiloxy groups,
dimethylsiloxane-methylvinylsiloxane copolymer endblocked at both terminals by dimethyl(3-glycidoxypropyl)siloxy groups,
(3-glycidoxypropyl)siloxane-dimethylsiloxane-methylvinylsiloxane copolymer,
3-methacryloxypropylsiloxane-dimethylsiloxane-methylvinylsiloxane copolymer,
3-methacryloxypropylsilsesquioxane-vinylsilsesquioxane copolymer,
3-glycidoxypropylsilsesquioxane-vinylsilsesquioxane copolymer.

Specific examples of the organopolysiloxane that lacks the organic functional group and that contains at least two silicon-bonded alkenyl groups per molecule are as follows:
dimethylpolysiloxane endblocked at both terminals by dimethylvinylsiloxy groups,
dimethylsiloxane-methylvinylsiloxane copolymer endblocked at both terminals by trimethylsiloxy groups,
dimethylsiloxane-methylvinylsiloxane copolymer endblocked at both terminals by dimethylvinylsiloxy groups,
methyltri(dimethylvinylsiloxy)silane,
methylphenylpolysiloxane endblocked at both terminals by dimethylvinylsiloxy groups,
dimethylsiloxane-methylvinylsiloxane copolymer endblocked at both terminals by dimethylphenylsiloxy groups, and
dimethylsiloxane-methylvinylsiloxane-methylphenylsiloxane copolymer endblocked at both terminals by dimethylvinylsiloxy groups.
   In addition, the specific examples of component (A) also apply here.

Specific examples of the organosilane that lacks the organic functional group and that contains at least two silicon-bonded hydrogen atoms per molecule are the specific examples of component (B) and in addition alkylsilane that contains two silicon-bonded hydrogen atoms and silylated aliphatic hydrocarbon that contains two silicon-bonded hydrogen atoms.

The organopolysiloxane that lacks the organic functional group and that contains at least two silicon-bonded hydrogen atoms per molecule can be exemplified by the specific examples of component (B); methylhydrogensiloxane oligomers, as represented by the formulas (HMe₂Si)₂O, (HMe₂SiO)₂SiMe₂, (HMe₂SiO)(SiMe₂)₂(OSiMe₂H), and (HMe₂SiO)₃SiMe; cyclic methylhydrogensiloxane oligomers (degree of polymerization=4 to 6); methyltri(dimethylhydrogensiloxy)silane; tetra(dimethylhydrogensiloxy)silane; methylhydrogenpolysiloxane with a degree of polymerization of 2 to 30 endblocked at both terminals by trimethylsiloxy groups; dimethylsiloxane-methylhydrogensiloxane copolymer with a degree of polymerization of 2 to 30 endblocked at both terminals by trimethylsiloxy groups; and dimethylpolysiloxane with a degree of polymerization of 3 to 30 endblocked at both terminals by dimethylhydrogensiloxy groups.

While all of these contain at least two silicon-bonded hydrogen atoms per molecule, the organosiloxane oligomers and organopolysiloxanes preferably contain an average of at least two silicon-bonded hydrogen atoms per molecule.

The organopolysiloxane that contains at least one organic functional group per molecule and at least two silicon-bonded hydrogen atoms per molecule can be specifically exemplified by
dimethylsiloxane-methyl(3-methacryloxypropyl)siloxane copolymer endblocked at both terminals by dimethylhydrogensiloxy groups,
dimethylsiloxane-methylhydrogensiloxane copolymer endblocked at both terminals by dimethyl(3-methacryloxypropyl)siloxy groups,
dimethylsiloxane-methyl(3-glycidoxypropyl)siloxane copolymer endblocked at both terminals by dimethylhydrogensiloxy groups, and
dimethylsiloxane-methylhydrogensiloxane copolymer endblocked at both terminals by dimethyl(3-glycidoxypropyl)siloxy groups.
   While all of these contain at least two silicon-bonded hydrogen atoms per molecule, the organosiloxane oligomers and organopolysiloxanes preferably contain an average of at least two silicon-bonded hydrogen atoms per molecule.

The molar ratio between the silicon-bonded hydrogen atom and the silicon-bonded alkenyl in the preceding hydrosilylation reaction-curable organopolysiloxane compositions may be a molar ratio sufficient to bring about the formation of a cured layer through sufficient crosslinking between the alkenyl-containing organopolysiloxane and the SiH-containing organosilane or organopolysiloxane. While it is preferably greater than 1:1, it may be 0.5 to 1.

The hydrosilylation reaction catalyst in the preceding hydrosilylation reaction-curable organopolysiloxane compositions is exemplified by the same examples as for component (C) and is preferably used in the same amount.

The above-described compositions comprising the organic functional group-containing, hydrosilylation reaction-curable organopolysiloxane preferably contain a hydrosilylation reaction retarder since the hydrosilylation reaction proceeds even at ambient temperatures. The hydrosilylation reaction retarder can be exemplified by the same examples as for the hydrosilylation reaction retarder used for the hydrosilylation reaction-curable organopolysiloxane resin composition comprising components (A), (B), and (C) and is preferably used in the same amount. The above-described compositions comprising the organic functional group-containing, hydrosilylation reaction-curable organopolysiloxane may contain microparticulate reinforcing silica as long as the optical transparency of the cured product is not impaired.

The composition comprising the organic functional group-containing, hydrosilylation reaction-curable organopolysiloxane is coated on the cured organopolysiloxane resin film and is cured by standing at ambient temperature or by heating. Curing by the application of heat is required in those instances where this composition contains a hydrosilylation reaction retarder and is therefore heat-curable.

The cured organopolysiloxane resin film having gas barrier properties according to the second embodiment of the present invention is characterized in that a layer of a cured organopolysiloxane having an organic group produced by polymerization between polymerizable organic functional groups, is formed on a film which is transparent in the visible region and comprises a cured organopolysiloxane resin obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst,
   and a transparent inorganic layer selected from the group consisting of a silicon oxynitride layer, silicon nitride layer, and silicon oxide layer is formed on the cured organopolysiloxane layer.

The organic group produced by polymerization between polymerizable organic functional groups is bonded to silicon atoms in the different organopolysiloxanes constituting the cured organopolysiloxane layer.

Viewed from the standpoint of adhesion of the transparent inorganic layer selected from a silicon oxynitride layer, silicon nitride layer, and silicon oxide layer, the organic group produced by polymerization between polymerizable organic functional groups is preferably an oxygen-containing organic group, and more preferably is oxygen-containing organic group consisting of carbon atom, hydrogen atom and oxygen atom, or consisting of carbon atom, hydrogen atom, oxygen atom and nitrogen atom. The oxygen-containing organic group preferably contains a carbonyl group, or a polar bond, e.g., a carboxylic acid ester bond, carboxylic acid amide bond, ether bond (C—O—C) and so forth.

Based on a consideration of the curability of the polymerizable organic functional group-containing organopolysiloxane, this organopolysiloxane must comprise a molecule that contains at least two polymerizable organic functional groups per molecule when the polymerizable organic functional groups participate in chain-growth polymerization, while this organopolysiloxane must comprise a molecule that has at least three polymerizable organic functional groups per molecule when step-growth polymerization operates. The polymerizable organic functional group may be up to 100 mole % of the total organic groups that are bonded through the C—Si bond in the polymerizable organic functional group-containing curable organopolysiloxane. For example, this value is 33.3 mole % in Synthesis Example 3 herein after described.

These polymerizable organic functional groups form crosslink points and render the organopolysiloxane curable. The transparent inorganic layer selected from the silicon oxynitride layer, silicon nitride layer, and silicon oxide layer readily adheres to the cured film formed by polymerization between the polymerizable organic functional groups in the polymerizable organic functional group-containing organopolysiloxane under consideration. Viewed from the standpoint of adhesion of the transparent inorganic layer, the polymerizable organic functional group is preferably an oxygen-containing polymerizable organic functional group, and more preferably an oxygen-containing polymerizable organic functional group consisting of carbon atom, hydrogen atom and oxygen atom, or consisting of carbon atom, hydrogen atom, oxygen atom and nitrogen atom. The oxygen-containing organic functional group preferably contains carbonyl group, or a polar bond, e.g., a carboxylic acid ester bond, carboxylic acid amide bond, ether bond (C—O—C) and so forth.

The layer of cured organopolysiloxane containing organic groups produced by the polymerization of the polymerizable organic functional groups with each other is formed by coating the polymerizable organic functional group-containing organopolysiloxane on the cured organopolysiloxane resin film, particularly free-standing film and curing by polymerizing the polymerizable organic functional groups with each other. When these polymerizable organic functional groups undergo polymerization with each other, the organic groups produced by the polymerization become crosslinking chains within this organopolysiloxane and the organopolysiloxane then cures by assuming a network configuration.

Based on a consideration of the ease of polymerization, the polymerizable organic functional group in the polymerizable organic functional group-containing organopolysiloxane is preferably the aforementioned acrylic functional group, epoxy functional group, oxetanyl functional group, or alkenyl ether group.

Other examples are a crotonyl functional group and a cinnamoyl functional group, which can be regarded as types of the acrylic functional group.
The acrylic functional group is known as acryloyl functional group, and its representative example is represented by the formula CH₂═CHCO—.

Preferred acrylic functional groups can be exemplified by an acryloxy functional group and acrylamide functional group;

Preferred acryloxy functional groups can be exemplified by an acryloxyalkyl group represented by CH₂═CHCOOR— (wherein R in the formulas is an alkylene group such as propylene) such as acryloxypropyl group, and by a methacryloxyalkyl group represented by CH₂═CH(CH₃)COOR— (wherein R in the formula is an alkylene group such as propylene) such as methacryloxypropyl group.
Preferred acrylamide functional groups can be exemplified by a N-alkyl-N-acrylamidealkyl group represented by CH₂═CHCON(R)— (wherein R in the formula is an alkyl group such as methyl) such as N-alkyl-N-acrylamidepropyl group, and by a N-alkyl-N-methacrylamide group represented by CH₂═C(CH₃)CON(R)— (wherein R in the formulas is an alkyl group such as methyl) such as N-alkyl-N-methacrylamidepropyl group.
The alkylene group here preferably has 2 to 6 carbon atoms

Preferred specific examples of the epoxy functional group are epoxymethyl group and 2-epoxyethyl group; a glycidoxyalkyl group such as β-glycidoxyethyl group and 3-glycidoxpropyl group; and an epoxycyclohexylalkyl group such as β-(3,4-epoxycyclohexyl)ethyl and 3-(3,4-epoxycyclohexyl)propyl. Preferred specific examples of the oxetanyl functional group are 2-oxetanylbutyl group and 3-(2-oxetanylbutyloxy)propyl group. Preferred specific examples of the alkenyl ether functional group are vinyloxyalkyl group, allyloxyalkyl group, and allyloxyphenyl group. This alkenyl has preferably 2 to 6 carbon atoms.

When the polymerizable organic functional group is an acrylic functional group or alkenyl ether group, for example, a vinyloxyalkyl group, polymerization can be effected by exposure to actinic energy radiation or high energy radiation, such as ultraviolet radiation, an electron beam, gamma radiation, and so forth. Polymerization can also be brought about by heating when the polymerizable organic functional group is an acrylic functional group. A radical polymerization initiator may also be used in the case of polymerization by the application of heat. When the polymerizable organic functional group is an epoxy functional group or an oxetanyl functional group, ring-opening polymerization can be brought about by exposure to ultraviolet radiation in the presence of a photopolymerization initiator. Ring-opening polymerization can also be brought about by the co-use of a catalyst such as an aliphatic amine, alicyclic amine, aromatic amine, imidazole, organic dicarboxylic acid, organic dicarboxylic anhydride, and so forth.

The polymerizable organic functional group-containing organopolysiloxane can be specifically exemplified by the following:

dimethylsiloxane-methyl(3-methacryloxypropyl)siloxane copolymer endblocked at both terminals by trimethylsiloxy groups, dimethylpolysiloxane endblocked at both terminals by dimethyl(3-methacryloxypropyl)siloxy groups, dimethylsiloxane-methyl(3-methacryloxypropyl)siloxane copolymer endblocked at both terminals by dimethyl(3-methacryloxypropyl)siloxy groups, 3-methacryloxypropylpolysilsesquioxane, 3-methacryloxypropylsilsesquioxane-phenylsilsesquioxane copolymer, 3-methacryloxypropylsilsesquioxane-methylsilsesquioxane copolymer; dimethylsiloxane-methyl(3-glycidoxypropyl)siloxane copolymer endblocked at both terminals by trimethylsiloxy groups, dimethylpolysiloxane endblocked at both terminals by dimethyl(3-glycidoxypropyl)siloxy groups, dimethylsiloxane-methyl(3-glycidoxypropyl)siloxane copolymer endblocked at both terminals by dimethyl(3-glycidoxypropyl)siloxy groups, 3-glycidoxypropylpolysilsesquioxane, β-(3,4-epoxycyclohexyl)ethylpolysilsesquioxane, 3-glycidoxypropylsilsesquioxane-phenylsilsesquioxane copolymer, and 3-glycidoxypropylsilsesquioxane-methylsilsesquioxane copolymer.

The layer of cured organopolysiloxane containing organic groups produced by the polymerization of the polymerizable organic functional groups with each other can also be formed by coating the cured organopolysiloxane resin film, particularly free-standing film with a curable organopolysiloxane that contains at least one polymerizable organic functional group and crosslinking group per molecule or composition thereof, polymerizing the polymerizable organic functional groups with each other and reacting the crosslinking groups with each other to cure the curable organopolysiloxane or composition thereof.

The curing mechanism for the polymerizable organic functional group-containing curable organopolysiloxane composition preferably proceeds through a condensation reaction or a hydrosilylation reaction. The crosslinking group is exemplified by silanol group and silicon-bonded hydrolyzable groups for the condensation reaction, and an alkenyl group and hydrosilyl group for the hydrosilylation reaction. Preferred silicon-bonded hydrolyzable groups can be exemplified by alkoxy, alkenyloxy, acyloxy, ketoxime, and alkylamine, wherein alkoxy is preferred and methoxy and ethoxy are more preferred considering the volatilization behavior of the alcohol produced by their hydrolysis.

An example of a curable organopolysiloxane that contains at least one polymerizable organic functional group and crosslinking group per molecule is a humidity-curable organopolysiloxane that contains at least three silicon-bonded hydrolyzable groups per molecule and at least one polymerizable organic functional group per molecule.

The following are examples of compositions comprising the condensation reaction-curable organopolysiloxane that contains at least one polymerizable organic functional group and crosslinking group per molecule:

(1) a curable composition comprising a condensation reaction catalyst and an organopolysiloxane that contains at least one polymerizable organic functional group per molecule and at least three silicon-bonded hydrolyzable groups per molecule, and

(2) a curable composition comprising a condensation reaction catalyst, an organopolysiloxane that contains at least one polymerizable organic functional group per molecule and one or two silicon-bonded hydrolyzable groups per molecule, and an organopolysiloxane that lacks the polymerizable organic functional group and that contains at least three silicon-bonded hydrolyzable groups.

The following are examples of compositions comprising hydrosilylation reaction-curable organopolysiloxane that has at least one polymerizable organic functional group and cross-linking group per molecule:

(1) a composition comprising an organopolysiloxane that contains at least two silicon-bonded alkenyl groups per molecule and at least one polymerizable organic functional group per molecule, an organosilane that contains at least two silicon-bonded hydrogen atoms per molecule and lacks the polymerizable organic functional group, and a hydrosilylation reaction catalyst, and

(2) a composition comprising an organopolysiloxane that contains at least one polymerizable organic functional group per molecule and at least two silicon-bonded alkenyl groups per molecule, an organopolysiloxane that contains at least two silicon-bonded hydrogen atoms per molecule and lacks the polymerizable organic functional group, and a hydrosilylation reaction catalyst.

Additional examples are

(3) a composition comprising an organopolysiloxane that contains at least two silicon-bonded alkenyl groups per molecule and that lacks the polymerizable organic functional group, an organopolysiloxane that contains at least one polymerizable organic functional group per molecule and at least two silicon-bonded hydrogen atoms per molecule, and a hydrosilylation reaction catalyst, and

(4) a composition comprising an organopolysiloxane that contains at least one polymerizable organic functional group per molecule and at least two silicon-bonded alkenyl groups per molecule, an organopolysiloxane that contains at least one polymerizable organic functional group per molecule and at least two silicon-bonded hydrogen atoms per molecule, and a hydrosilylation reaction catalyst.

Because the hydrosilylation reaction proceeds even at ambient temperature, these compositions (1) to (4) also preferably incorporate a hydrosilylation reaction retarder.

This hydrosilylation reaction retarder is exemplified by the same hydrosilylation reaction retarders as cited for the composition comprising components (A), (B), and (C) and is preferably used in the same amount.

The molar ratio between the silicon-bonded hydrogen and the silicon-bonded alkenyl in the preceding compositions may be a molar ratio sufficient to bring about the formation of a cured layer through sufficient crosslinking between the alkenyl-containing organopolysiloxane and the SiH-containing organosilane or organopolysiloxane. While it is preferably greater than 1:1, it may be 0.5 to 1.

Specific examples of the organopolysiloxane that contains at least one polymerizable functional group per molecule and at least two silicon-bonded alkenyl groups per molecule are as follows:
dimethylsiloxane-methyl(3-methacryloxypropyl)siloxane copolymer endblocked at both terminals by dimethylvinylsiloxy groups,
dimethylsiloxane-methylvinylsiloxane copolymer endblocked at both terminals by dimethyl(3-methacryloxypropyl)siloxy group,
dimethylsiloxane-methyl(3-glycidoxypropyl)siloxane copolymer endblocked at both terminals by dimethylvinylsiloxy groups, and
dimethylsiloxane-methylvinylsiloxane copolymer endblocked at both terminals by dimethyl(3-glycidoxypropyl)siloxy groups.

Specific examples of the organopolysiloxane that contains at least one organic functional group per molecule and at least two silicon-bonded hydrogen atoms per molecule are as follows:
dimethylsiloxane-methyl(3-methacryloxypropyl)siloxane copolymer endblocked at both terminals by dimethylhydrogensiloxy groups,
dimethylsiloxane-methylhydrogensiloxane copolymer endblocked at both terminals by dimethyl(3-methacryloxypropyl)siloxy groups,
dimethylsiloxane-methyl(3-glycidoxypropyl)siloxane copolymer endblocked at both terminals by dimethylhydrogensiloxy groups, and
dimethylsiloxane-methylhydrogensiloxane copolymer endblocked at both terminals by dimethyl(3-glycidoxypropyl)siloxy groups.

Specific examples of the organosilane that contains at least two silicon-bonded hydrogen atoms per molecule and that lacks the polymerizable organic functional group, the organopolysiloxane that contains at least two silicon-bonded hydrogen atoms per molecule and that lacks the polymerizable organic functional group, and the organopolysiloxane that contains at least two silicon-bonded alkenyl groups per molecule and that lacks the polymerizable organic functional group are the same those as already described.

The aforementioned composition comprising a polymerizable organic functional group-containing, condensation reaction-curable organopolysiloxane and the aforementioned composition comprising a polymerizable organic functional group-containing, hydrosilylation reaction-curable organopolysiloxane may contain microparticulate reinforcing silica insofar as the optical transparency of the cured product is not impaired.

The aforementioned polymerizable organic functional group-containing curable organopolysiloxane is thinly coated on the cured organopolysiloxane resin film, and curing is brought about by crosslinking the curable organopolysiloxane and polymerizing the polymerizable organic functional groups with each other. This polymerization between the polymerizable organic functional groups is carried out as described above. The crosslinking mechanism for the curable organopolysiloxane itself can be exemplified by condensation.

When the polymerizable organic functional groups are polymerized with each other among a plurality of curable organopolysiloxanes that have at least one polymerizable organic functional group per molecule and the curable organopolysiloxane is crosslinked, the plurality of organopolysiloxanes then cure by assuming a network configuration.

The aforementioned polymerizable organic functional group-containing, condensation reaction-curable organopolysiloxane per se or a composition thereof is coated on the cured organopolysiloxane resin film, and curing is effected by a condensation reaction among the silicon-bonded hydrolyzable groups brought about by standing at ambient temperature or heating and the polymerizable organic functional groups are polymerized with each other. The auxiliary use of heating or an hydrolysis/condensation reaction catalyst as described above is necessary in those instances where humidity-induced hydrolysis/condensation does not occur or hydrolysis/condensation proceeds with difficulty.

The aforementioned composition comprising the polymerizable organic functional group-containing, hydrosilylation reaction-curable organopolysiloxane is coated on the cured organopolysiloxane resin film, and curing is effected by a hydrosilylation reaction brought about by standing at ambient temperature or heating and by polymerization of the polymerizable organic functional groups with each other. Curing by the application of heat is required in those instances where this composition contains a hydrosilylation reaction retarder and is therefore heat-curable. The conditions for polymerizing the polymerizable organic functional groups are as described above in paragraphs [0058] to [0059].

When the aforementioned organic functional group-containing curable organosilane per se or a composition thereof, the aforementioned organic functional group-containing curable organopolysiloxane per se or a composition thereof, or the aforementioned polymerizable organic functional group-containing curable organopolysiloxane per se or a composition thereof is either a high viscosity liquid or a solid at ambient temperature, it is preferably rendered coatable as a thin film by dissolution in an organic solvent. Once coating on the cured organopolysiloxane resin film has been carried out, curing is preferably effected after the organic solvent has been evaporated off, said organic solvent being evaporated off by heating at low temperature or by exposure to a hot air current.

The organic solvent for this purpose preferably does not cause hydrolysis of silicon-bonded hydrogen atoms and preferably is easily evaporated off by heating to no more than 200° C. Suitable organic solvents can be exemplified by ketones such as acetone, methyl ethyl ketone, methyl isobutyl ketone, and so forth; aromatic hydrocarbons such as toluene, xylene, and so forth; aliphatic hydrocarbons such as heptane, hexane, octane, and so forth; ethers such as THF, dioxane, and so forth; as well as dimethylformamide and N-methylpyrrolidone.

These organic solvents are used in a quantity that enables dissolution of the aforementioned organosilane, organosilane composition, organopolysiloxane, or organopolysiloxane composition and coating thereof in a thin layer.

Brush application, blade coating, roller coating, spin coating, spraying, and dip coating are examples of methods that can be used to coat the surface of the cured organopolysiloxane resin film with the aforementioned organic functional group-containing curable organosilane per se or a composition thereof, the aforementioned organic functional group-containing curable organopolysiloxane per se or a composition thereof, the aforementioned polymerizable organic functional group-containing curable organopolysiloxane per se or a composition thereof, or polymerizable organic functional group- and crosslinking group-containing curable organopolysiloxane per se or composition thereof.

The thickness of the layer of organic functional group-containing cured organopolysiloxane and the thickness of the layer of cured organopolysiloxane having organic groups formed by the polymerization of polymerizable organic functional groups with each other are to be a thickness sufficient to also coat the elevations of microscopic depressions and elevations on the surface of the cured organopolysiloxane resin film, and a thin layer is preferred. That is, a thickness appropriate for a primer layer is preferred.

The cured organopolysiloxane resin films, particularly free-standing film having gas barrier properties of the third embodiment of the present invention are characterized in that a hydrosilyl group- or silanol-containing cured organopolysiloxane layer is formed on a film which is transparent in the visible region and comprises a cured organopolysiloxane resin obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst,
   and a transparent inorganic layer selected from the group consisting of a silicon oxynitride layer, silicon nitride layer, and silicon oxide layer is formed on the cured organopolysiloxane layer.

This hydrosilyl group is bonded to a portion of the silicon atoms in the organopolysiloxane forming the cured organopolysiloxane, and the silanol is bonded to a portion of the silicon atoms in the organopolysiloxane forming the cured organopolysiloxane. Both of the hydrosilyl group and the silanol group may be bonded to a portion of the silicon atoms in the organopolysiloxane forming the cured organopolysiloxane layer. A small amount of silicon atom-bonded hydrolysable groups besides the hydrosilyl group and/or the silanol group may be bonded to a portion of the silicon atoms in the organopolysiloxane forming the cured organopolysiloxane layer. Such hydrolysable groups are usually originated in curable organosilanes or curable organopolysiloxanes for forming the cured organopolysiloxane layer.

The hydrosilyl group-containing cured organopolysiloxane layer can be formed by coating and curing, onto the cured organopolysiloxane resin film, a hydrosilylation reaction-curable organopolysiloxane composition comprising (a) an organopolysiloxane that has an average of at least 1.2 alkenyl groups per molecule, (b) an organosilicon compound having at least two silicon-bonded hydrogen atoms, that is, hydrosilyl groups per molecule, and (c) a hydrosilylation reaction catalyst wherein the molar ratio between the hydrosilyl groups in component (b) and the alkenyl groups in component (a) is greater than 1.0. An average of at least 1.2 alkenyl groups is present per molecule. Based on a consideration of the curability, preferably an average of at least 1.5 alkenyl groups is present per molecule and more preferably an average of at least 2.0 is present per molecule.

When component (b) is an organosilicon compound that has two silicon-bonded hydrogen atoms per molecule, component (a) must comprise a molecule that has at least three C_{2 to} C₁₀ alkenyl groups per molecule in order for component (a) to cure through its addition reaction with component (b).

When component (a) has two alkenyl groups per molecule, component (b) must comprise a molecule that contains at least three silicon-bonded hydrogen atoms per molecule in order for component (a) to cure through its addition reaction with component (b).

While the major portion of component (a) must be an organopolysiloxane containing at least three alkenyl groups per molecule or an organopolysiloxane containing at least two alkenyl groups per molecule, component (a) may contain an organopolysiloxane containing one alkenyl group per molecule.

From the standpoint of adhesion of the transparent inorganic layer, the molar ratio between the hydrosilyl groups in component (b) and the alkenyl groups in component (a) is preferably from at least 1.05 to no more than 1.5 and more preferably from at least 1.1 to no more than 1.5.

However, since there is a risk that the silicon-bonded hydrogen atoms (hydrosilyl groups) may be consumed by mechanisms other than the hydrosilylation reaction, it is necessary to confirm that silicon-bonded hydrogen atoms (hydrosilyl groups) remain after curing. Detection of the absorption peak for the hydrosilyl group with an infrared spectrophotometer can be used for confirmation.

Component (a) can be exemplified by the same examples as provided for component (A), and additional examples are the same examples as provided above for the organopolysiloxane that contains at least two silicon-bonded alkenyl groups per molecule and that lacks the organic functional group (see paragraph [0085]). Example (b) can be exemplified by the same examples as provided for component (B), and additional examples are the same examples as provided above for the organopolysiloxane that contains at least two silicon-bonded hydrogen atoms per molecule and that lacks the organic functional group (see paragraph [0087]). Component (c) can be exemplified by the same examples as provided above for component (C).

The hydrosilylation reaction-curable composition comprising components (a), (b), and (c) preferably incorporates a hydrosilylation reaction retarder since the hydrosilylation reaction proceeds even at ambient temperature. The hydrosilylation reaction retarder can be exemplified by the same examples as for the hydrosilylation reaction retarder used for the composition comprising components (A), (B), and (C) and may be used in the same amount.

The aforementioned hydrosilylation reaction-curable organopolysiloxane composition comprising components (a), (b), and (c), or the hydrosilylation reaction-curable organopolysiloxane composition comprising components (a), (b), and (c) and a hydrosilylation reaction retarder can be coated on the cured organopolysiloxane resin film and cured by standing at ambient temperature or heating. Brush application, blade coating, roller coating, spin coating, spraying, and dip coating are examples of methods that can be used to coat the surface of the cured organopolysiloxane resin film with the aforementioned hydrosilylation reaction-curable organopolysiloxane composition.

When the aforementioned hydrosilylation reaction-curable organopolysiloxane composition is either a high viscosity liquid or a solid at ambient temperature, it is preferably rendered coatable as a thin film by dissolution in an organic solvent. Once coating on the cured organopolysiloxane resin film has been carried out, curing is preferably effected after the organic solvent has been evaporated off, said organic solvent being evaporated off by heating at low temperature or by exposure to a hot air current.

The thickness of the hydrosilyl group-containing cured organopolysiloxane layer is to be a thickness sufficient to also coat the elevations of microscopic depressions and elevations on the surface of the cured organopolysiloxane resin film, and a thin layer is preferred. That is, a thickness appropriate for a primer layer is preferred.

The silanol-containing cured organopolysiloxane layer can be formed by coating the cured organopolysiloxane resin film with an organosilane that contains three silicon-bonded hydrolyzable groups per molecule and lacks the organic functional group and carrying out a hydrolysis/condensation reaction in the presence or absence of an hydrolysis/condensation reaction catalyst. Formation can also be carried out by coating the cured organopolysiloxane resin film with a mixture of an organosilane that contains three silicon-bonded hydrolyzable groups per molecule and lacks the organic functional group and an organosilane that contains one or two silicon-bonded hydrolyzable groups per molecule and lacks the organic functional group, and carrying out a hydrolysis/condensation reaction in the presence or absence of an hydrolysis/condensation reaction catalyst. Formation can also be carried out by using, instead of the aforementioned organosilane, an organopolysiloxane that contains at least three silicon-bonded hydrolyzable groups per molecule and lacks the organic functional group, or composition thereof.

Specific examples of the aforementioned organosilanes and organopolysiloxane and specific examples of the hydrolysis/condensation reaction catalyst are the same as those already explained in paragraphs [0074] to [0078] and [0069].

Aforementioned condensation reaction-curable organosilane or composition thereof, or the aforementioned condensation reaction-curable curable organopolysiloxane or composition thereof can be coated on the cured organopolysiloxane resin film and cured by standing at ambient temperature or heating. The auxiliary use of heating or an hydrolysis/condensation reaction catalyst is necessary in those instances where the silicon-bonded hydrolyzable group does not undergo humidity-induced hydrolysis/condensation or is refractory to hydrolysis/condensation.

When the aforementioned condensation reaction-curable organosilane or composition thereof, or the aforementioned condensation reaction-curable curable organopolysiloxane or composition thereof is either a high viscosity liquid or a solid at ambient temperature, it is preferably rendered coatable as a thin film by dissolution in an organic solvent. Once coating on the cured organopolysiloxane resin film has been carried out, curing is preferably effected after the organic solvent has been evaporated off, said organic solvent being evaporated off by heating at low temperature or by exposure to a hot air current.

Brush application, blade coating, roller coating, spin coating, spraying, and dip coating are examples of methods that can be used to coat the surface of the cured organopolysiloxane resin film with the aforementioned condensation reaction-curable organosilane or composition thereof, or the aforementioned condensation reaction-curable organopolysiloxane or composition thereof.

The thickness of the silanol group-containing cured organopolysiloxane layer is to be a thickness sufficient to also coat the elevations of microscopic depressions and elevations on the surface of the cured organopolysiloxane resin film, and a thin layer is preferred. That is, a thickness appropriate for a primer layer is preferred.

Viewed from the standpoint of adhesion of the transparent inorganic layer selected from the group consisting of the silicon oxynitride layer, silicon nitride layer, and silicon oxide layer, the silanol group-containing cured organopolysiloxane layer contains preferably 0.5 to 40 molar percent of silanol group, and more preferably 1 to 30 molar percent of silanol group relative to the whole silicon atoms, namely, the molar ratio of silanol groups to silicon atoms in the silanol group-containing cured organopolysiloxane is preferably on average from 0.005 to 0.40, and more preferably on average from 0.01 to 0.30.

The layer of cured organopolysiloxane that contains organic functional groups, or organic groups produced by polymerization between polymerizable organic functional groups, or hydrosilyl groups or silanol groups, coats over the microscopic contaminants (foreign material) on the surface of the cured organopolysiloxane resin film that have become attached during the production sequence and fills in depressions, and, because of this, when the transparent inorganic layer selected from the group consisting of a silicon oxynitride layer, silicon nitride layer, and silicon oxide layer is formed thereon, a good quality transparent inorganic layer, that is, transparent inorganic film selected from the group consisting of a silicon oxynitride layer, that is, silicon oxynitride film, silicon nitride layer, that is, silicon nitride film, and silicon oxide layer, that is, silicon oxide film can be formed, wherein the production of voids and cracks in this transparent inorganic layer is prevented.

The cured organopolysiloxane resin film having gas barrier properties of the fourth embodiment of the present invention is a cured organopolysiloxane resin film having gas barrier properties produced by forming a silicon oxynitride layer by a reactive ion plating procedure on a hydrosilyl group-containing cured organopolysiloxane resin film which is transparent in the visible region and is obtained by a crosslinking reaction between
(A) an organopolysiloxane resin that is represented by the average siloxane unit formula

RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
   in the presence of
(C) a hydrosilylation reaction catalyst.

The above-cited components (A) to (C) and the cured organopolysiloxane resin film are as described for the cured organopolysiloxane resin film having gas barrier properties according to the first, second, and third embodiments, and component (A) is preferably the component (A) specified in claims 4 and 5.

The hydrosilylation group-containing cured organopolysiloxane resin film can be formed by curing at a molar ratio between the hydrosilyl groups in component (B) and the unsaturated aliphatic hydrocarbyl groups in component (A) of 1.05 to 1.50. However, since there is a risk that the silicon-bonded hydrogen atoms, that is, hydrosilyl group may be consumed by mechanisms other than the hydrosilylation reaction, it is necessary to confirm that silicon-bonded hydrogen atoms, that is, hydrosilyl group remain after curing. Detection of the absorption peak for the hydrosilyl group with an infrared spectrophotometer can be used for confirmation.

The presence of hydrosilyl groups in the cured organopolysiloxane resin film enables the formation of a good quality silicon oxynitride layer when a silicon oxynitride layer is formed on the surface of this film by reactive ion plating.

The cured organopolysiloxane resin film, particularly free-standing film in the cured organopolysiloxane resin film, particularly free-standing film having gas barrier properties of the present invention are a heat-resistant crosslinked material that exhibits a poor water absorption property, and as a consequence they do not impair film formation during the vapor deposition of silicon oxynitride, silicon nitride, or silicon oxide and in particular do not impair film formation by the evaporation of low molecular weight components during vacuum vapor deposition (vacuum film formation). As a consequence, they are well adapted for the formation of a gas barrier inorganic layer on their surface using a variety of vacuum vapor deposition (vacuum film formation) methods.

Thus, a cured organopolysiloxane resin film having gas barrier properties, comprising a silicon oxynitride layer, silicon nitride layer, or silicon oxide layer which has been vapor-deposited on a cured organopolysiloxane resin film, particularly free-standing film that lack a specific absorption band in the visible region from 400 nm to 800 nm, can be produced by the vapor deposition and preferably the vacuum vapor deposition, that is, vacuum film formation of silicon oxynitride, silicon nitride, or silicon oxide at a temperature for the cured organopolysiloxane resin film, particularly free-standing film of no more than 300° C. This temperature condition of no more than 300° C. is necessary in order to prevent deformation and/or pyrolysis of the cured organopolysiloxane resin film, particularly free-standing film, and a more preferred temperature is no more than 250° C.

In the inventive cured organopolysiloxane resin film, particularly free-standing film having gas barrier properties, a cured organopolysiloxane layer containing organic functional groups, or organic groups produced by polymerization among polymerizable organic functional groups, or hydrosilyl groups or silanol groups is layered on a cured organopolysiloxane resin film, and a silicon oxynitride layer, that is, silicon oxynitride film, silicon nitride layer, that is, silicon nitride film, or silicon oxide layer, that is, silicon oxide film is formed thereon.

Also, a silicon oxynitride layer produced by reactive ion plating is formed on a hydrosilyl group-containing cured organopolysiloxane resin film.

As a consequence, the silicon oxynitride layer, that is, silicon oxynitride film, silicon nitride layer, that is, silicon nitride film, or silicon oxide layer, that is, silicon oxide film is uniform and there is good adhesiveness between the individual layers and the individual layers are thus not easily delaminated from each other. The silicon oxynitride, silicon nitride, and silicon oxide are in each case the noncrystalline material.

The silicon oxynitride layer, that is, silicon oxynitride film, silicon nitride layer, that is, silicon nitride film, and silicon oxide layer, that is, silicon oxide film each exhibit an excellent optical transparency and for this reason the optical transparency of the cured organopolysiloxane resin film is not impaired; however, the oxygen fraction (O/(O+N)) in the silicon oxynitride layer, that is, silicon oxynitride film must be about 40% to 80% in order for it to exhibit an optical transparency of 90% or more. Here, the amount of oxygen can be determined according to XPS measurements from the intensity ratio between the peak due to SiO in the vicinity of 105 eV for Si 2p and that due to SiOₓN_{y} in the vicinity of 103 to 104 eV for Si 2p.

The preferred ranges for the values of x and y in the silicon oxynitride (SiOₓN_{y}) are values that provide an oxygen fraction (O/(O+N)) of approximately 40% to 80%.

Among the three layers cited above, the silicon oxynitride layer, that is, silicon oxynitride film is the best from the standpoint of high barrier properties and transparency.

Silicon oxynitride is a composite of silicon oxide and silicon nitride, and its transparency increases at a high silicon oxide content while its gas barrier performance increases at a high silicon nitride content. Silicon oxynitride is also known as nitrided silicon oxide and also simply as SiON.

Vapor deposition is the method used to form the silicon oxynitride layer, that is, silicon oxynitride film on the cured organopolysiloxane resin film, and reactive physical vapor deposition procedures are preferred within this sphere. Among the reactive physical vapor deposition procedures, reactive ion plating is preferred, followed by reactive sputtering. Because these procedures enable vapor deposition to be carried out at relatively low temperatures, i.e., 300° C. and below, there is almost no thermal influence on the cured organopolysiloxane resin film.

In ion plating, the depositing material is ionized by generating a plasma between the substrate and a crucible holding the depositing material within a chamber; a negative voltage is applied to the substrate; and the ionized depositing material, accelerated to high velocities, collides with the substrate to form a thin film of the depositing material. Direct current discharge excitation and high frequency excitation are typical ion plating methods.

Within the realm of ion plating, reactive ion plating is a method in which a reactive gas has been introduced into the chamber and a thin film comprising a compound between the ionized depositing material and the reactive gas is formed. The following methods, inter alia, can be used to form a silicon oxynitride film: (1) a method in which silicon oxide or silicon dioxide is used as the depositing material and a gas functioning as a nitrogen source, e.g., nitrogen gas, nitrous oxide gas, ammonia, and so forth, is introduced into the chamber; (2) a method in which silicon nitride is used as the depositing material and oxygen gas is introduced into the chamber; and (3) a method in which silicon is used as the depositing material and oxygen gas and a gas functioning as a nitrogen source, e.g., nitrogen gas, nitrous oxide gas, ammonia, and so forth, are introduced into the chamber. Reactive ion plating offers the advantages of good adhesiveness with the substrate and the ability to form a fine, dense silicon oxynitride film.

The method described in JP Kokai 2004-050821 (JP 2004-050821 A) is a specific example of reactive ion plating. This method uses an ion plating apparatus in which a hearth is provided in the lower part of a film formation chamber, a plasma gun is located in a side region of the film formation chamber, and a substrate is disposed in the upper region of the film formation chamber. A silicon oxide rod introduced into the hearth is heated by a plasma beam from the plasma gun, thereby inducing evaporation of the silicon oxide; the evaporated silicon oxide is ionized and reacts with nitrogen gas that has been introduced into the film formation chamber to give silicon oxynitride; and bonding of this to the substrate surface results in the formation of a silicon oxynitride film. In an example, the discharge current is 120 A; argon gas is employed as a carrier gas; N₂ gas is employed as a reactive gas; the pressure during film formation is 3 mTorr, that is, 0.40 Pa; and the substrate temperature is room temperature.

In reactive sputtering, inert gas ions are generated by an ion gun or plasma discharge and are accelerated by an electric field onto a target (depositing material), resulting in the ejection of the elements and/or compounds at the surface and the deposition on the substrate of compounds while reacting with a reactive gas. A silicon oxynitride film can be formed, by the following methods: (1) a method in which silicon nitride or silicon dioxide is used as the target and argon gas and nitrogen gas are introduced into the chamber; (2) a method in which silicon nitride (Si₃N₄) is used as the target and argon gas and oxygen gas are introduced into the chamber; and (3) a method in which silicon (Si) is used as the target and argon gas, nitrogen gas, and oxygen gas are introduced into the chamber. A two-pole sputtering apparatus or a magnetron sputtering apparatus is used as the apparatus, while a direct current procedure and high frequency are typical discharge methods. Reactive sputtering offers good control of the elemental composition and can form a fine and dense silicon oxynitride layer that is, silicon oxynitride film.

Chemical vapor deposition (CVD) is another method by which silicon oxynitride layer, that is, silicon oxynitride film can be formed on the cured organopolysiloxane resin film, and plasma CVD, catalytic CVD, and photo-CVD are preferred among CVD methods. The reaction gases are typically monosilane gas (SiH₄), a gas that functions as a nitrogen source (e.g., nitrous oxide gas, nitric oxide gas, ammonia, and so forth), and hydrogen gas.

In order to form a silicon oxynitride layer, that is, silicon oxynitride film by plasma CVD, for example, monosilane gas, ammonia gas, and nitrogen gas are introduced into a vacuum container in which the cured organopolysiloxane resin film has been mounted; a plasma is generated by, for example, the application of a high frequency discharge while holding the internal pressure at 0.1 to 10 Torr, that is, 13.3 to 1330 Pa; and film-forming species produced when the introduced gases are excited within the plasma are deposited on the cured organopolysiloxane resin film.

In order to form a silicon oxynitride layer, that is, silicon oxynitride film by catalytic CVD, for example, monosilane gas, ammonia gas, and hydrogen gas are introduced into a vacuum container in which the cured organopolysiloxane resin film is mounted; the introduced gases are decomposed activated by heating a tungsten wire to about 1700° C. to form a silicon oxynitride layer, that is, silicon oxynitride film on the cured organopolysiloxane resin film, which is being maintained at about 70° C.

In order to form a silicon oxynitride layer, that is, silicon oxynitride film by photo-CVD, for example, monosilane gas, ammonia gas, and nitrogen gas are introduced into a vacuum container in which the cured organopolysiloxane resin film is mounted; excitation is carried out by exposing the gases to ultraviolet radiation or laser light while holding the internal pressure at 1 to 100 Torr, that is, 133 to 13300 Pa; and film-forming species produced by the excitation are deposited on the cured organopolysiloxane resin film.

The silicon oxynitride (SiOₓN_{y}) layer, that is, silicon oxynitride film may be formed on one side or on both sides of the cured organopolysiloxane resin film. In addition, the vapor deposition process, that is, film formation process may be carried out a plurality of times.

The thickness of the silicon oxynitride (SiOₓN_{y}) layer, that is, silicon oxynitride (SiOₓN_{y}) film will vary with the application and the required gas barrier performance, but the range of 10 nm to 1 μm is preferred and the range of 10 nm to 200 nm is more preferred. An overly thick silicon oxynitride layer, that is, silicon oxynitride film impairs the flexibility of the cured organopolysiloxane resin film having gas barrier properties and results in the facile introduction of cracks into the silicon oxynitride layer, that is, silicon oxynitride film itself. When too thin, the silicon oxynitride layer, that is, silicon oxynitride film is easily ruptured by contact with sources of potential damage and the gas barrier properties are readily reduced.

The silicon nitride layer, that is, silicon nitride film can be formed on the cured organopolysiloxane resin film by, inter alia, vacuum vapor deposition methods, ion beam-assisted vapor deposition methods, sputtering methods, ion plating methods, and reactive physical vapor deposition methods, and can also be formed by CVD methods such as plasma CVD and thermal CVD.

The method described in JP Kokai 2004-142351 (JP 2004-142351 A) is a specific example of the formation of a silicon nitride (Si₃N₄) layer by RF magnetron sputtering. The sputtering device may be, for example, a batch-type sputtering device (SPF-530H, ANELVA Corporation). The substrate film is mounted in a chamber; a target of silicon nitride having a sinter density of 60% is mounted in the chamber; and the target-to-substrate film gap, that is, TS gap is set to 50 mm.

The interior of the chamber is then evacuated to a final vacuum of 2.5×10⁻⁴ Pa; argon gas is introduced into the chamber at a flow rate of 20 sccm; and a silicon nitride layer, that is, silicon nitride film is formed on the substrate film by RF magnetron sputtering at an applied power of 1.2 kW.

JP Kokai 2000-212747 (JP2000-212747 A) discloses a concrete example of methods to form a silicon nitride (Si₃N₄) layer by plasma CVD. A substrate film is mounted on a lower electrode, namely, earth electrode in the chamber of parallel plate type of plasma CVD apparatus PE401 (which is a product of ANELVBA), and the interior of the chamber is then evacuated to a final vacuum of 0.1 mTorr, that is, 0.013 Pa. Hexamethyldisilazane vaporized by heating and nitrogen gas are introduced into the chamber. An electric power with 200 W and 13.56 Hz is applied between an upper electrode and the earth electrode to form plasma, and the pressure in the chamber is maintained at 50 mTorr, that is, 6.5 Pa, to form a silicon nitride layer, that is, silicon nitride film on the substrate film.

The film thickness is suitably in the range of 5 to 500 nm and more preferably 10 to 300 nm. The silicon nitride layer, that is, silicon nitride film may be formed on one side or both sides of the cured organopolysiloxane resin film. In addition, the vapor deposition process, that is, film formation process may be run a plural number of times.

The silicon oxide layer, that is, silicon oxide film may be formed on one side or on both sides of the cured organopolysiloxane resin film by a physical vapor deposition, that is, PVD method such as vacuum deposition, sputtering, ion plating, and so forth, or by a chemical vapor deposition, that is, CVD method.

Vacuum deposition uses SiO₂ alone, a mixture of Si and SiO₂, a mixture of Si and SiO, or a mixture of SiO and SiO₂ as its vapor deposition source material and uses resistance heating, high frequency induction heating, or electron beam heating as its heating method.

Sputtering uses SiO₂ alone, a mixture of Si and SiO₂, a mixture of Si and SiO, or a mixture of SiO and SiO₂ as its target material and uses a direct-current discharge, alternating-current discharge, high-frequency discharge, or an ion beam as its sputtering method. Oxygen gas or steam is used as the reactive gas in reactive sputtering.

The silicon oxide (SiOₓ) in the silicon oxide film is composed of Si, SiO, SiO₂, and so forth, and the ratios thereamong will vary with the process conditions. A preferred range for the value of x in the silicon oxide (SiOₓ) is x=0.1 to 2, and x=2 gives silicon dioxide (SiO₂).

Viewed from the standpoint of the gas barrier properties, the thickness of the silicon oxide layer, that is, silicon oxide film on the cured organopolysiloxane resin film is preferably 5 to 800 nm and more preferably 70 to 500 nm. The silicon oxide layer, that is, silicon oxide film may be formed on one side or on both sides of the cured organopolysiloxane resin film. Moreover, the vapor deposition process, that is, film formation process may be carried out a plurality of times.

### EXAMPLES

Examples of the present invention and comparative examples will now be described.

The weight-average molecular weight and the molecular weight distribution of the methylphenylvinylpolysiloxane resins in the synthesis examples were measured by gel permeation chromatography, that is, GPC. The GPC instrument used consisted of a refractive index detector and two TSKgel GMHXL-L columns which is a product of TOSOH Corporation) installed in an HLC-8020GPC which is a product of TOSOH Corporation. The sample was submitted to measurement of the elution curve as the 2 weight % chloroform solution. The calibration curve was constructed using polystyrene standards of known weight-average molecular weight. The weight-average molecular weight was therefore determined on a polystyrene standards basis.

The ²⁹Si-NMR spectra and ¹H-NMR spectra of the methylphenylvinylpolysiloxane resins were taken with a Bruker ACP-300 Spectrometer.

The infrared absorption spectra of the methylphenylvinylpolysiloxane resins were measured in transmission mode using a Nicolet Nexus 670 spectrophotometer.

The surface roughness of the silicon oxynitride layers, that is, silicon oxynitride films was observed using an AFM-DI5000 atomic force microscope abbreviated as AFM at a 25 μm scan.

The thickness of the silicon oxynitride layers, that is, silicon oxynitride films was measured by observation of their cross section with a JEOL 2100F transmission electron microscope abbreviated as TEM.

The light transmittance of the cured organopolysiloxane resin film having gas barrier properties was measured using a Model 3100PC spectrophotometer from SHIMADZU CORPORATION.

The water vapor transmission rate of the cured organopolysiloxane resin film per se and of the silicon oxynitride layer, that is, silicon oxynitride film-bearing cured organopolysiloxane resin film was measured by the Mocon method using a Mocon Permatran-W3-31 instrument for measuring water vapor transmission.

### Synthesis Example 1

While operating at room temperature, 320 mL water was introduced into a four-neck flask equipped with a reflux condenser, dropping funnel, thermometer, and stirrer and 340 mL toluene, 157 g phenyltrichlorosilane, 20.0 g vinyldimethylchlorosilane, and 20.6 g tetraethoxysilane were then gradually added dropwise thereto over 45 minutes from the dropping funnel while stirring. After stirring for an additional 30 minutes at room temperature, the toluene layer was washed with water to neutrality. The toluene layer was transferred to a separate single-mouth flask and the toluene was then removed by distillation to a solids concentration of 50 weight %. After this, 130 mg potassium hydroxide was added and heating under reflux was carried out for 16 hours while removing water azeotropically.

After completion of the reaction, the potassium hydroxide was neutralized with a small amount of vinyldimethylchlorosilane and washing with water was then carried out to achieve complete neutrality for the toluene layer, after which the toluene layer was dried by the introduction of drying agent thereinto. After removal of the drying agent, the toluene was eliminated under reduced pressure to obtain 108 g methylphenylvinylpolysiloxane resin as a white solid. Measurement of the molecular weight of this methylphenylvinylpolysiloxane resin gave a weight-average molecule weight of 2300 and a number-average molecular weight of 1800. The average siloxane unit formula of this methylphenylvinylpolysiloxane resin as determined from the ²⁹Si-NMR spectrum was [ViMe₂SiO_{1/2}]_{0.15}[PhSiO_{3/2}]_{0.76}[SiO_{4/2}]_{0.09} (in the formula, Vi indicates vinyl group and Me indicates methyl group. There were 2.2 vinyl groups per molecule).

### Example 1

A 75 weight % toluene solution of the methylphenylvinylpolysiloxane resin of Synthesis Example 1 was mixed with 1,4-bis(dimethylsilyl)benzene so as to provide a molar ratio of the silicon-bonded hydrogen atoms in the latter to the vinyl groups in the former of 1.2 and this was thoroughly stirred. A 1,3-divinyl-1,1,3,3-tetramethyldisiloxane solution (platinum content=5 weight %) of a platinum-1,3-divinyl-1,1,3,3-tetramethyldisiloxane complex was subsequently added in an amount that provided 2 ppm for the weight of the platinum metal with reference to the weight of the solids fraction in the aforementioned polysiloxane+1,4-bis(dimethylsilyl)benzene mixture; stirring was continued to give a casting solution.

This casting solution was cast onto a glass substrate; after standing for about 1 hour at room temperature, the toluene was evaporated off by heating for about 2 hours at 100° C. and curing was then effected by heating for about 3 hours at 150° C. This was followed by cooling to room temperature by standing, and a free-standing film comprising cured methylphenylvinylpolysiloxane resin was then obtained by peeling the cured methylphenylvinylpolysiloxane resin from the glass substrate.

This film was transparent and had a thickness of 100 μm. Measurement of the light transmittance of this film yielded a light transmittance at 400 to 700 nm of at least 85%. A polarized light dependence was not seen when the light transmittance of this film was measured using a polarizer. It was also confirmed that birefringence was not present in this film. It was confirmed from the IR spectrum that silicon-bonded hydrogen atoms, that is, hydrosilyl groups, SiH groups remained present on the surface of the film in an amount corresponding to the excess amount of SiH groups relative to vinyl groups before curing. Measurement of the bending strength of the cured methylphenylvinylpolysiloxane resin film having a width of 1.27 cm, a length of 5.08 cm, and a thickness of 0.25 cm using an Autograph which is a product of SHIMADZU CORPORATION gave a Young's modulus of 1.4 GPa and a bending strength of 50 MPa.

A silicon oxynitride layer, that is, silicon oxynitride film was formed on one side of this film having a width of 10 cm, a length of 10 cm, and a thickness of 100 μm using reactive ion plating. A 100 nm-thick silicon oxynitride layer, that is, silicon oxynitride film was formed using a silicon oxide rod as the film formation starting material and using nitrogen gas as the reactive gas; the discharge current was 120 A, the pressure during film formation was 5 mTorr, that is, 0.67 Pa, and the cycle was carried out two times. The surface roughness Ra of the silicon oxynitride layer, that is, silicon oxynitride film was 1.32 to 1.77 nm. This silicon oxynitride layer, that is, silicon oxynitride film-bearing cured methylphenylvinylpolysiloxane resin film had a light transmittance at 400 to 700 nm of at least 80% and had a water vapor transmission rate of 0.37 to 0.56 g/m²·day.

### Comparative Example 1

The water vapor transmission rate measured on the cured methylphenylvinylpolysiloxane resin free-standing film obtained in Example 1 was 90 to 100 g/m²·day.

### Comparative Example 2

Using the methylphenylvinylpolysiloxane resin of Synthesis Example 1 and the 1,4-bis(dimethylsilyl)benzene used in Example 1, a free-standing film comprising the cured methylphenylvinylpolysiloxane resin was obtained under the same conditions as in Example 1, except that the molar ratio of the silicon-bonded hydrogen atoms in the latter to the vinyl groups in the former was made 1.0. This film was transparent and had a thickness of 100 μm. Measurement of the light transmittance of this film gave a light transmittance of at least 85% at 400 to 700 nm. A polarized light dependence was not seen when the light transmittance of this film was measured using a polarizer. It was also confirmed that birefringence was not present in this film. It was confirmed from the IR spectrum that hydrosilyl groups, that is, SiH groups did not remain on the surface. The properties measured by the bending test were the same as for the film of Example 1.

A silicon oxynitride layer, that is, silicon oxynitride film was formed on one side of this film having a width of 10 cm, a length of 10 cm, and a thickness of 100 μm by reactive ion plating under the same conditions as in Example 1. According to TEM, the thickness of the silicon oxynitride layer, that is, silicon oxynitride film was 85 nm and its surface roughness Ra was 5.5 nm. The light transmittance at 400 to 700 nm was at least 80%. The water vapor transmission rate was 5.4 g/m²·day.

### Synthesis Example 2

65.8 g of a water-based colloidal silica dispersion of which trade name is Snowtex, and a product of Nissan Chemical Industries, Ltd. was introduced into a flask, and, while stirring at room temperature, 7.0 g of acetic acid and a mixture of 5.0 mL of distilled water, 29.2 g of methyltrimethoxysilane, and 38.8 g of 3-glycidoxypropyltrimethoxysilane were added. The contents of the flask were then heated to raise the temperature to 55° C., and stirring was carried out for 30 minutes while maintaining the temperature within the flask at 50-60° C. This was followed by cooling to 20° C. and stirring for an additional 30 minutes. Dilution was subsequently carried out by introducing 54.3 g of isopropyl alcohol, and dibutyltin dilaurate (6.0 g as solids) was gradually added as curing catalyst. The precipitate was removed from the obtained reaction mixture, and aging was carried out by standing at room temperature for 2 to 3 days. The resulting aged reaction mixture was employed as a coating solution.

### Example 2

A free-standing film comprising cured methylphenylvinylpolysiloxane resin was prepared using the same conditions as in Comparative Example 2. The coating solution prepared in Synthesis Example 2 was spin-coated for 30 seconds at 1500 rpm on one side of this film having a width of 10 cm, a length of 10 cm, and a thickness of 100 μm; the toluene was evaporated off by holding for 30 minutes at 100° C.; and curing was then carried out by holding for 120 minutes at 150° C. The resulting free-standing film was subjected to formation thereon of a silicon oxynitride layer, that is, silicon oxynitride film using ion plating under the same conditions as in Example 1. This silicon oxynitride layer, that is, silicon oxynitride film had a thickness of 85 nm and a surface roughness Ra of 0.71 to 0.93 nm. This silicon oxynitride layer, that is, silicon oxynitride film-bearing cured organopolysiloxane resin film had a light transmittance of at least 80% at 400 to 700 nm, and its water vapor transmission rate was 0.25 to 0.26 g/m²·day.

### Synthesis Example 3

80 g of toluene, 49.7 g of 3-methacryloxypropyltrimethoxysilane, 79.3 g of phenyltrimethoxysilane, 1 g of a 50 weight % aqueous solution of cesium hydroxide, 200 g of methanol, and 40 mg of 2,6-di-t-butyl-4-methylphenol were introduced into a flask and heated under reflux for 1 hour while stirring. During this interval, 250 g of the solvent, that is, (methanol) was removed by distillation and the same amount of toluene was simultaneously added. After the removal of almost all the methanol and water, heating to 105° C. was carried out over about 1 hour. After cooling to room temperature, additional toluene was added to give the approximately 15 weight % solution and 3 g acetic acid was added and stirring was carried out for 30 minutes. The resulting toluene solution was washed with water and filtered across a membrane filter with a pore diameter of 1 μm. The toluene was then removed from the filtrate under reduced pressure.

40 g of the poly(phenyl-co-3-methacryloxypropyl)silsesquioxane thus obtained was dissolved in 60 g of propylene glycol monoethyl ether acetate. To this solution was added Irgacure 819 which is a photocure initiator, and a product of Ciba Specialty Chemicals at 3 weight % of the silsesquioxane, thus yielding a coating solution.

### Example 3

A free-standing film comprising cured methylphenylvinylpolysiloxane resin was obtained under the same conditions as in Comparative Example 2. The coating solution obtained in Synthesis Example 3 was spin coated for 30 seconds at 2500 rpm on one side of this film having a width of 10 cm, a length of 10 cm, and a thickness of 100 μm. The 3-methacryloxy groups were polymerized with each other by exposing the coated side for 15 seconds to ultraviolet radiation where exposure dose is 30 mW/cm² using a 200 W Hg—Xe lamp; this was followed by curing by holding for 120 minutes at 150° C. On the one side of the resulting coated film was formed a 100 nm-thick silicon oxynitride layer, that is, silicon oxynitride film by ion plating under the same conditions as in Example 1. According to visual observation, the silicon oxynitride layer, that is, silicon oxynitride film was uniform and free of peeling.

### Example 4

Using the methylphenylvinylpolysiloxane resin of Synthesis Example 1 and the 1,4-bis(dimethylsilyl)benzene used in Example 1, a free-standing film comprising cured methylphenylvinylpolysiloxane resin was obtained under the same conditions as in Example 1, except that the molar ratio of the silicon-bonded hydrogen atoms in the latter to the vinyl groups in the former was made 1.0.

On one side of this film having a width of 10 cm, a length of 10 cm, and a thickness of 100 μm was spin coated at 2500 rpm for 30 seconds, as for film fabrication in Example 1, a hydrosilylation reaction-curable organopolysiloxane composition comprising a toluene solution of a methylphenylvinylpolysiloxane resin with the average unit formula [ViMe₂SiO_{1/2}]_{0.25}[PhSiO_{3/2}]_{0.76}, a methylphenylhydrogenpolysiloxane resin with the average unit formula [HMe₂SiO_{1/2}]_{0.60}[PhSiO_{3/2}]_{0.40}, and the platinum-based catalyst used in Example 1 and having a molar ratio between the hydrosilyl group and vinyl group of 1.2, and curing was carried out by holding for 120 minutes at 150° C. On the one side of the resulting coated film was formed a 100 nm-thick silicon oxynitride layer that is, silicon oxynitride film under the same conditions as in Example 1. According to visual observation, the silicon oxynitride layer that is, silicon oxynitride film was uniform and free of peeling.

### INDUSTRIAL APPLICABILITY

The cured organopolysiloxane resin film having gas barrier properties of the present invention is useful as a film substrate for the transparent electrodes in electroluminescent displays, liquid-crystal displays, and so forth; as a back sheet for crystalline silicon solar cells; and as a substrate for amorphous silicon solar cells.

The inventive method of producing the cured organopolysiloxane resin film having gas barrier properties is useful for the facile and precise production of the cured organopolysiloxane resin film having gas barrier properties.

### DESCRIPTION OF THE REFERENCE SYMBOLS

1: cured organopolysiloxane resin film
2: organic functional group-containing cured organopolysiloxane layer
3: silicon oxynitride layer

1. A cured organopolysiloxane resin film having gas barrier properties characterized in that an organic functional group-containing cured organopolysiloxane layer is formed on a film which is transparent in the visible region and comprises a cured organopolysiloxane resin obtained by a crosslinking reaction between
(A) an organopolysiloxane resin that is represented by the average siloxane unit formula
RₐSiO_{4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
in the presence of
(C) a hydrosilylation reaction catalyst,
and a transparent inorganic layer selected from the group consisting of a silicon oxynitride layer, silicon nitride layer, and silicon oxide layer is formed on the cured organopolysiloxane layer.

2. The cured organopolysiloxane resin film having gas barrier properties according to claim 1, characterized in that the organic functional group is an oxygen-containing organic functional group.

3. The cured organopolysiloxane resin film having gas barrier properties according to claim 2, characterized in that the oxygen-containing organic functional group is an acrylic functional group, epoxy functional group, or oxetanyl functional group.

4. The cured organopolysiloxane resin film having gas barrier properties according to claim 3, characterized in that the acrylic functional group is an acryloxyalkyl group or methacryloxyalkyl group and the epoxy functional group is a glycidoxyalkyl group or epoxycyclohexylalkyl group.

5. The cured organopolysiloxane resin film having gas barrier properties according to claim 1, characterized in that the organopolysiloxane resin represented by the average siloxane unit formula (1) is composed of at least one siloxane unit represented by formula
[X_{(3-b)}R¹_{b}SiO_{1/2}]
(in the formula, X is C_{2 to} C₁₀ monovalent unsaturated aliphatic hydrocarbyl, R¹ is C₁ to C₁₀ monovalent hydrocarbyl other than X, and b is 0, 1, or 2) and at least one siloxane unit represented by formula
[R²SiO_{3/2}]
(in the formula, R² is C_{1 to} C₁₀ monovalent hydrocarbyl other than X), or at least one siloxane unit represented by formula
[X_{(3-b)}R¹_{b}SiO_{1/2}]
(in the formula, X is C_{2 to} C₁₀ monovalent unsaturated aliphatic hydrocarbyl, R¹ is C_{1 to} C₁₀ monovalent hydrocarbyl other than X, and b is 0, 1, or 2), at least one siloxane unit represented by formula
[R²SiO_{3/2}]
(in the formula, R² is C_{1 to} C₁₀ monovalent hydrocarbyl other than X), and at least one siloxane unit represented by formula
[SiO_{4/2}].

6. The cured organopolysiloxane resin film having gas barrier properties according to claim 5, characterized in that the organopolysiloxane resin is represented by the average siloxane unit formula
[X_{(3-b)}R¹_{b}SiO_{1/2}]ᵥ[R²SiO_{3/2}]_{w} (2)
(in the formula, X, R¹, R², and b are defined as in claim 5, 0.8<w<1.0, and v+w=1) or by the average siloxane unit formula
[X_{(3-b)}R¹_{b}SiO_{1/2}]ₓ[R²SiO_{3/2}]_{y}[SiO_{4/2}]_{z} (3)
(in the formula, X, R¹, R², and b are defined as in claim 5, 0<x<0.4, 0.5<y<1, 0<z<0.4, and x+y+z=1).

7. A method of producing the cured organopolysiloxane resin film having gas barrier properties according to claim 1, said method being characterized by coating and curing an organic functional group-containing curable organosilane or composition thereof or an organic functional group-containing curable organopolysiloxane or composition thereof on a film which is transparent in the visible region and comprises a cured organopolysiloxane resin obtained by a crosslinking reaction between
(A) an organopolysiloxane resin that is represented by the average siloxane unit formula
RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
in the presence of
(C) a hydrosilylation reaction catalyst,
to form on said film an organic functional group-containing cured organopolysiloxane layer; and
then forming, by vapor deposition, a transparent inorganic layer selected from the group consisting of a silicon oxynitride layer, silicon nitride layer, and silicon oxide layer, on the cured organopolysiloxane layer.

8. The method of producing a cured organopolysiloxane resin film having gas barrier properties according to claim 7, characterized in that the organic functional group-containing curable organosilane or composition thereof is condensation reaction-curable, the organic functional group-containing curable organopolysiloxane is condensation reaction-curable, and the organic functional group-containing curable organopolysiloxane composition is condensation reaction-curable or hydrosilylation reaction-curable.

9. The method of producing a cured organopolysiloxane resin film having gas barrier properties according to claim 7, characterized in that the organic functional group is an oxygen-containing organic functional group.

10. The method of producing a cured organopolysiloxane resin film having gas barrier properties according to claim 9, characterized in that the oxygen-containing organic functional group is an acrylic functional group, epoxy functional group, or oxetanyl functional group.

11. The method of producing a cured organopolysiloxane resin film having gas barrier properties according to claim 10, characterized in that the acrylic functional group is an acryloxyalkyl group or methacryloxyalkyl group and the epoxy functional group is a glycidoxyalkyl group or epoxycyclohexylalkyl group.

12. The method of producing a cured organopolysiloxane resin film having gas barrier properties according to claim 7, characterized in that the silicon oxynitride layer is formed by a reactive ion plating procedure.

13. A cured organopolysiloxane resin film having gas barrier properties characterized in that a layer of cured organopolysiloxane having organic groups produced by polymerization between polymerizable organic functional groups, is formed on a film which is transparent in the visible region and comprises a cured organopolysiloxane resin obtained by a crosslinking reaction between
(A) an organopolysiloxane resin that is represented by the average siloxane unit formula
RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
in the presence of
(C) a hydrosilylation reaction catalyst,
and a transparent inorganic layer selected from the group consisting of a silicon oxynitride layer, silicon nitride layer, and silicon oxide layer is formed on the cured organopolysiloxane layer.

14. The cured organopolysiloxane resin film having gas barrier properties according to claim 13, characterized in that the polymerizable organic functional group is an oxygen-containing polymerizable organic functional group, and the organic group is an oxygen-containing organic group.

15. The cured organopolysiloxane resin film having gas barrier properties according to claim 14, characterized in that the oxygen-containing polymerizable organic functional group is an acrylic functional group, epoxy functional group, oxetanyl functional group, or alkenyl ether functional group, and the oxygen-containing organic group contains a carbonyl group or ether bond.

16. The cured organopolysiloxane resin film having gas barrier properties according to claim 15, characterized in that the acrylic functional group is an acryloxyalkyl group, methacryloxyalkyl group, acrylamidealkyl group or methacrylamidealkyl group; the epoxy functional group is a glycidoxyalkyl group or epoxycyclohexylalkyl group; the alkenyl ether functional group is a vinyloxyalkyl group; and the oxygen-containing organic group has a carboxylic acid ester bond, carboxylic acid amide bond or ether bond.

17. The cured organopolysiloxane resin film having gas barrier properties according to claim 13, characterized in that the organopolysiloxane resin represented by the average siloxane unit formula (1) is composed of at least one siloxane unit represented by formula
[X_{(3-b)}R¹_{b}SiO_{1/2}]
(in the formula, X is C_{2 to} C₁₀ monovalent unsaturated aliphatic hydrocarbyl, R¹ is C_{1 to} C₁₀ monovalent hydrocarbyl other than X, and b is 0, 1, or 2) and at least one siloxane unit represented by formula
[R²SiO_{3/2}]
(in the formula, R² is C_{1 to} C₁₀ monovalent hydrocarbyl other than X), or at least one siloxane unit represented by formula
[X_{(3-b)}R¹_{b}SiO_{1/2}]
(in the formula, X is C_{2 to} C₁₀ monovalent unsaturated aliphatic hydrocarbyl, R¹ is C_{1 to} C₁₀ monovalent hydrocarbyl other than X, and b is 0, 1, or 2), at least one siloxane unit represented by formula
[R²SiO_{3/2}]
(in the formula, R² is C_{1 to} C₁₀ monovalent hydrocarbyl other than X), and at least one siloxane unit represented by formula
[SiO_{4/2}].

18. The cured organopolysiloxane resin film having gas barrier properties according to claim 17, characterized in that the organopolysiloxane resin is represented by the average siloxane unit formula
[X_{(3-b)}R¹_{b}SiO_{1/2}]ᵥ[R²SiO_{3/2}]_{w} (2)
(in the formula, X, R¹, R², and b are defined as in claim 13, 0.8<w<1.0, and v+w=1) or by the average siloxane unit formula
[X_{(3-b)}R¹_{b}SiO_{1/2}]ₓ[R²SiO_{3/2}]_{y}[SiO_{4/2}]_{z} (3)
(in the formula, X, R¹, R², and b are defined as in claim 13, 0<x<0.4, 0.5<y<1, 0<z<0.4, and x+y+z=1).

19. A method of producing the cured organopolysiloxane resin film having gas barrier properties according to claim 13, said method being characterized by coating an organopolysiloxane that has polymerizable organic functional groups on a film which is transparent in the visible region and comprises a cured organopolysiloxane resin obtained by a crosslinking reaction between
(A) an organopolysiloxane resin that is represented by the average siloxane unit formula
RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
in the presence of
(C) a hydrosilylation reaction catalyst;
crosslinking said organopolysiloxane by polymerization of the polymerizable organic functional groups with each other to form a layer of cured organopolysiloxane having organic groups on said film; and
then forming, by vapor deposition, a transparent inorganic layer selected from the group consisting of a silicon oxynitride layer, silicon nitride layer, and silicon oxide layer, on the cured organopolysiloxane layer.

20. A method of producing a cured organopolysiloxane resin film having gas barrier properties according to claim 13, said method being characterized by coating a polymerizable organic functional group- and crosslinking group-containing curable organopolysiloxane or composition thereof on a film which is transparent in the visible region and comprises a cured organopolysiloxane resin obtained by a crosslinking reaction between
(A) an organopolysiloxane resin that is represented by the average siloxane unit formula
RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
in the presence of
(C) a hydrosilylation reaction catalyst;
reacting the crosslinking groups with each other and polymerizing the polymerizable organic functional groups with each other to form a layer of cured organopolysiloxane having organic groups on said film; and
then forming, by vapor deposition, a transparent inorganic layer selected from the group consisting of a silicon oxynitride layer, silicon nitride layer, and silicon oxide layer, on the cured organopolysiloxane layer.

21. The method of producing a cured organopolysiloxane resin film having gas barrier properties according to claim 19, characterized in that the polymerizable organic functional group is an oxygen-containing polymerizable organic functional group and the organic group is an oxygen-containing organic group.

22. The method of producing a cured organopolysiloxane resin film having gas barrier properties according to claim 21, characterized in that the oxygen-containing polymerizable organic functional group is an acrylic functional group, epoxy functional group, oxetanyl functional group, or alkenyl ether functional group, and the oxygen-containing organic group contains an carbonyl group or ether bond.

23. The method of producing a cured organopolysiloxane resin film having gas barrier properties according to claim 22, characterized in that the acrylic functional group is an acryloxyalkyl group, methacryloxyalkyl group, acrylamidealkyl group or methacrylamidealkyl group; the epoxy functional group is a glycidoxyalkyl group or epoxycyclohexylalkyl group; and the alkenyl ether functional group is a vinyloxyalkyl group, and the oxygen-containing organic group has a carboxylic acid ester bond, carboxylic acid amide bond or ether bond.

24. The method of producing a cured organopolysiloxane resin film having gas barrier properties according to claim 19, characterized in that the silicon oxynitride layer is formed by a reactive ion plating procedure.

25. A cured organopolysiloxane resin film having gas barrier properties characterized in that a hydrosilyl group- or silanol group-containing cured organopolysiloxane layer is formed on a film which is transparent in the visible region and comprises a cured organopolysiloxane resin obtained by a crosslinking reaction between
(A) an organopolysiloxane resin that is represented by the average siloxane unit formula
RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
in the presence of
(C) a hydrosilylation reaction catalyst,
and a transparent inorganic layer selected from the group consisting of a silicon oxynitride layer, silicon nitride layer, and silicon oxide layer is formed on the cured organopolysiloxane layer.

26. The cured organopolysiloxane resin film having gas barrier properties according to claim 25, characterized in that the organopolysiloxane resin represented by the average siloxane unit formula (1) is composed of at least one siloxane unit represented by formula
[X_{(3-b)}R¹_{b}SiO_{1/2}]
(in the formula, X is C_{2 to} C₁₀ monovalent unsaturated aliphatic hydrocarbyl, R¹ is C_{1 to} C₁₀ monovalent hydrocarbyl other than X, and b is 0, 1, or 2) and at least one siloxane unit represented by formula
[R²SiO_{3/2}]
(in the formula, R² is C_{1 to} C₁₀ monovalent hydrocarbyl other than X), or at least one siloxane unit represented by formula
[X_{(3-b)}R¹_{b}SiO_{1/2}]
(in the formula, X is C_{2 to} C₁₀ monovalent unsaturated aliphatic hydrocarbyl, R¹ is C_{1 to} C₁₀ monovalent hydrocarbyl other than X, and b is 0, 1, or 2), at least one siloxane unit represented by formula
[R²SiO_{3/2}]
(in the formula, R² is C_{1 to} C₁₀ monovalent hydrocarbyl other than X), and at least one siloxane unit represented by formula
[SiO_{4/2}].

27. The cured organopolysiloxane resin film having gas barrier properties according to claim 26, characterized in that the organopolysiloxane resin is represented by the average siloxane unit formula
[X_{(3-b)}R¹_{b}SiO_{1/2}]ᵥ[R²SiO_{3/2}]_{w} (2)
(in the formula, X, R¹, R², and b are defined as in claim 26, 0.8<w<1.0, and v+w=1) or by the average siloxane unit formula
[X_{(3-b)}R¹_{b}SiO_{1/2}]ₓ[R²SiO_{3/2}]_{y}[SiO_{4/2}]_{z} (3)
(in the formula, X, R¹, R², and b are defined as in claim 26, 0<x<0.4, 0.5<y<1, 0<z<0.4, and x+y+z=1).

28. A method of producing the cured organopolysiloxane resin film having gas barrier properties according to claim 25, said method being characterized by coating and curing a hydrosilylation reaction-curable organopolysiloxane composition comprising
(a) an organopolysiloxane that has at least two alkenyl groups per molecule,
(b) an organosilicon compound that has at least two silicon-bonded hydrogen atoms per molecule, and
(c) a hydrosilylation reaction catalyst
wherein the molar ratio between the hydrosilyl groups in component (b) and the alkenyl groups in component (a) is at least 1.05,
on a film which is transparent in the visible region and comprises a cured organopolysiloxane resin obtained by a crosslinking reaction between
(A) an organopolysiloxane resin that is represented by the average siloxane unit formula
RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
in the presence of
(C) a hydrosilylation reaction catalyst,
to form a hydrosilyl group-containing cured organopolysiloxane layer on said film; and forming, by vapor deposition, a transparent inorganic layer selected from the group consisting of a silicon oxynitride layer, silicon nitride layer, and silicon oxide layer, on the cured organopolysiloxane layer.

29. A method of producing the cured organopolysiloxane resin film having gas barrier properties according to claim 25, said method being characterized by coating and curing a condensation reaction-curable organosilane, condensation reaction-curable organosilane composition, condensation reaction-curable organopolysiloxane, or condensation reaction-curable organopolysiloxane composition on a film which is transparent in the visible region and comprises a cured organopolysiloxane resin obtained by a crosslinking reaction between
(A) an organopolysiloxane resin that is represented by the average siloxane unit formula
RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
in the presence of
(C) a hydrosilylation reaction catalyst,
to form a silanol group-containing cured organopolysiloxane layer on said film; and forming, by vapor deposition, a transparent inorganic layer selected from the group consisting of a silicon oxynitride layer, silicon nitride layer, and silicon oxide layer, on the cured organopolysiloxane layer.

30. The method of producing a cured organopolysiloxane resin film having gas barrier properties according to claim 28, characterized in that the silicon oxynitride layer is formed by a reactive ion plating procedure.

31. A method of producing a cured organopolysiloxane resin film having gas barrier properties, said method being characterized by
forming a silicon oxynitride layer by a reactive ion plating procedure on a hydrosilyl group-containing cured organopolysiloxane resin film which is transparent in the visible region and is obtained by a crosslinking reaction between
(A) an organopolysiloxane resin that is represented by the average siloxane unit formula
RₐSiO_{(4-a)/2} (1)
(in the formula, R is C_{1 to} C₁₀ monovalent hydrocarbyl and a is a number with an average value in the range 0.5<a<2) and that has an average of at least 1.2 C_{2 to} C₁₀ unsaturated aliphatic hydrocarbyls per molecule and
(B) an organosilicon compound having at least two silicon-bonded hydrogen atoms per molecule
(wherein the molar ratio between the hydrosilyl groups in component (B) and the unsaturated aliphatic hydrocarbyl in component (A) is 1.05 to 1.50)
in the presence of
(C) a hydrosilylation reaction catalyst.
